(19) United States
(12) Patent Application Publication
(10) Pub. No.: US 2024/0292602 A1
(43) Pub. Date: Aug. 29, 2024

(54) SEMICONDUCTOR MEMORY DEVICE

(71) Applicant: Samsung Electronics Co., Ltd., Suwon-si (KR)

(72) Inventors: Sang Ho Lee, Suwon-si (KR); Moon Young Jeong, Suwon-si (KR); Dong Soo Woo, Suwon-si (KR); Yoon Gi Hong, Suwon-si (KR)

(21) Appl. No.: 18/462,614

(22) Filed: Sep. 7, 2023

(30) Foreign Application Priority Data
Feb. 23, 2023 (KR) 10-2023-0024435

(51) Int. Cl. H10B 12/00

(52) U.S. Cl. CPC H10B 12/482; H10B 12/315; H10B 12/488

(57) ABSTRACT

A semiconductor memory device includes a bit line extended in a first direction on a substrate, a first word line extended in a second direction on the bit line, a second word line extended in the second direction on the bit line and spaced apart from the first word line in the first direction, a back gate electrode between the first word line and the second word line and extended in the second direction, a first active pattern between the first word line and the back gate electrode on the bit line, and a second active pattern between the first word line and the back gate electrode on the bit.

### CROSS-REFERENCE TO RELATED APPLICATION

This application claims priority from Korean Patent Application No. 10-2023-0024435 filed on Feb. 23, 2023 in the Korean Intellectual Property Office and all the benefits accruing therefrom under 35 U.S.C. 119, the contents of which in its entirety are herein incorporated by reference.

### TECHNICAL FIELD

The present disclosure relates to a semiconductor memory device, and more particularly, to a semiconductor memory device that includes a vertical channel transistor (VCT).

### BACKGROUND

It may be desirable to increase the degree of integration of a semiconductor memory device to achieve excellent performance and low cost, which may be desired by consumers. In the case of the semiconductor memory device, the degree of integration may be a factor that determines the price of a product, and as such, the increased degree of integration has been especially desired.

In a case of a two-dimensional or planar semiconductor memory device, the degree of integration may be determined by an area occupied by a unit memory cell, and as such, it is greatly affected by the level of the technology for forming a fine pattern. However, since high-priced and complex equipment is required for forming the fine pattern, the degree of integration of the two-dimensional semiconductor memory device is increasing but is still restrictive. Therefore, semiconductor memory devices including a vertical channel transistor having a channel that is extended in a vertical direction have been proposed.

### SUMMARY

An object of the present disclosure is to provide a semiconductor memory device having improved degree of integration and electrical characteristics.

The objects of the present disclosure are not limited to those mentioned above and additional objects of the present disclosure, which are not mentioned herein, will be clearly understood by those skilled in the art from the following description of the present disclosure.

According to an aspect of the present disclosure, there is provided a semiconductor memory device comprising a bit line extended in a first direction on a substrate, a first word line extended in a second direction on the bit line, a second word line extended in the second direction on the bit line and spaced apart from the first word line in the first direction, a back gate electrode between the first word line and the second word line and extended in the second direction, a first active pattern between the first word line and the back gate electrode on the bit line, and a second active pattern between the first word line and the back gate electrode on the bit line, wherein the back gate electrode includes a first region comprising a first conductive material and a second region comprising a second conductive material different from the first conductive material, and the first region of the back gate electrode is between the second region of the back gate electrode and the bit line.

According to another aspect of the present disclosure, there is provided a semiconductor memory device comprising a bit line extended in a first direction on a substrate, a first active pattern on the bit line, a second active pattern on the bit line and spaced apart from the first active pattern in the first direction, a first word line between the first active pattern and the second active pattern and extended in the second direction, a second word line between the first active pattern and the second active pattern, the second word line extended in the second direction and spaced apart from the first word line in the first direction, a gate isolation pattern on the bit line, the gate isolation pattern including a horizontal portion and a protrusion portion, the horizontal portion is between the first word line and the bit line and between the second word line and the bit line, the protrusion portion is between the first word line and the second word line, and a width of the horizontal portion in the first direction is greater than that of the protrusion portion in the first direction, a back gate electrode on the bit line, the back gate electrode spaced apart from the first word line and the second word line in the first direction and the back gate electrode extended in the second direction, and data storage patterns connected to the first active pattern and the second active pattern, wherein the back gate electrode includes a first region comprising a first conductive material and a second region comprising a second conductive material different from the first conductive material, and the first region of the back gate electrode is between the second region of the back gate electrode and the bit line.

According to still another aspect of the present disclosure, there is provided a semiconductor memory device comprising a peripheral gate structure on a substrate, a bit line extended in a first direction on the peripheral gate structure, a shielding conductive line adjacent to the bit line on the peripheral gate structure and extended in the first direction, a first word line extended in a second direction on the bit line and the shielding conductive line, a second word line extended in the second direction on the bit line and the shielding conductive line and spaced apart from the first word line in the first direction, a back gate electrode between the first word line and the second word line and extended in the second direction, a first active pattern between the first word line and the back gate electrode on the bit line, a second active pattern between the first word line and the back gate electrode on the bit line, contact patterns connected to the first active pattern and the second active pattern and data storage patterns respectively connected to the contact patterns, wherein each of the first active pattern and the second active pattern comprises a single crystalline semiconductor material, and the back gate electrode includes a first region comprising a first conductive material and a second region comprising a second conductive material different from the first conductive material.

### BRIEF DESCRIPTION OF THE DRAWINGS

The above and other aspects and features of the present disclosure will become more apparent by describing in detail example embodiments thereof with reference to the attached drawings, in which:

FIG. 1 is a layout view illustrating a semiconductor memory device according to some embodiments of the present disclosure.

FIG. 2 is a cross-sectional view taken along lines A-A and B-B of FIG. 1.

FIG. 3 is a cross-sectional view taken along lines C-C and D-D of FIG. 1.

FIG. 4 is an enlarged view illustrating a portion P of FIG. 2.

FIGS. 5, 6, and 7 are views illustrating a semiconductor memory device according to some embodiments of the present disclosure.

FIGS. 8, 9, and 10 are views illustrating a semiconductor memory device according to some embodiments of the present disclosure.

FIGS. 11 and 12 are views illustrating a semiconductor memory device according to some embodiments of the present disclosure.

FIGS. 13 and 14 are views illustrating a semiconductor memory device according to some embodiments of the present disclosure.

FIGS. 15 and 16 are views illustrating a semiconductor memory device according to some embodiments of the present disclosure.

FIGS. 17 and 18 are views illustrating a semiconductor memory device according to some embodiments of the present disclosure.

FIGS. 19, 20, 21, 22, and 23 are views illustrating a semiconductor memory device according to some embodiments of the present disclosure.

FIGS. 24, 25, 26, 27, 28, 29, 30, 31, 32, 33, 34, 35, 36, 37, 38, 39, 40, 41, 42, 43, 44, 45, 46, 47, 48, 49, 50, 51, 52, 53, 54, 55, 56, 57, 58, 59, 60, 61, 62, and 63 are views illustrating a method for manufacturing a semiconductor memory device according to some embodiments of the present disclosure.

### DETAILED DESCRIPTION OF THE DISCLOSURE

It will be understood that, although the terms “first”, “second”, etc. may be used herein to describe various elements or components, these elements or components should not be limited by these terms. These terms are only used to distinguish one element or component from another element or component. Therefore, a first element or component discussed below could be termed a second element or component without departing from the technical spirits of the present disclosure.

To clarify the present disclosure, parts that are not connected with the description will be omitted, and the same elements or equivalents are referred to by the same reference numerals throughout the specification. Further, since sizes and thicknesses of constituent members shown in the accompanying drawings are arbitrarily given for better understanding and ease of description, the present disclosure is not limited to the illustrated sizes and thicknesses. In the drawings, the thickness of layers, films, panels, regions, etc., are exaggerated for clarity. In the drawings, for better understanding and ease of description, thicknesses of some layers and areas are excessively displayed.

It will be understood that when an element such as a layer, film, region, or substrate is referred to as being “on” another element, it can be directly on the other element or intervening elements may also be present. The term “connected” may be used herein to refer to a physical and/or electrical connection between two elements, and it can be directly connected or intervening elements may also be present. In contrast, when an element is referred to as being “directly on” another element or “directly connected” to another element, there are no intervening elements present. Further, spatially relative terms, such as “beneath,” “below,” “lower,” “above,” “upper,” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations), and the spatially relative descriptors used herein may be interpreted accordingly.

In addition, unless explicitly described to the contrary, the word “comprises”, and variations such as “comprises” or “comprising”, will be understood to imply the inclusion of stated elements but not the exclusion of any other elements. As used herein, the phrase “at least one of A, B, and C” refers to a logical (A OR B OR C) using a non-exclusive logical OR, and should not be construed to mean “at least one of A, at least one of B and at least one of C.” As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, steps, operations, elements and/or components, but do not preclude the presence or addition of one or more other features, steps, operations, elements, components and/or groups thereof. The term “and/or” includes any and all combinations of one or more of the associated listed items.

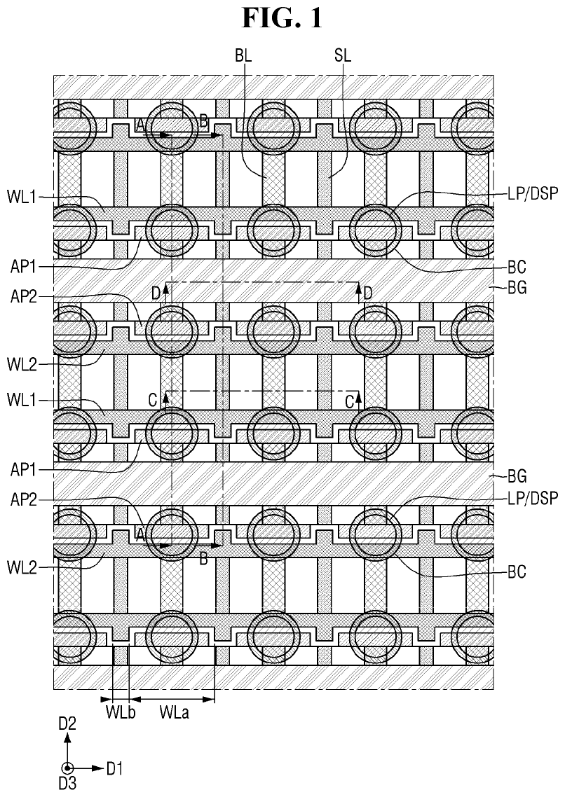

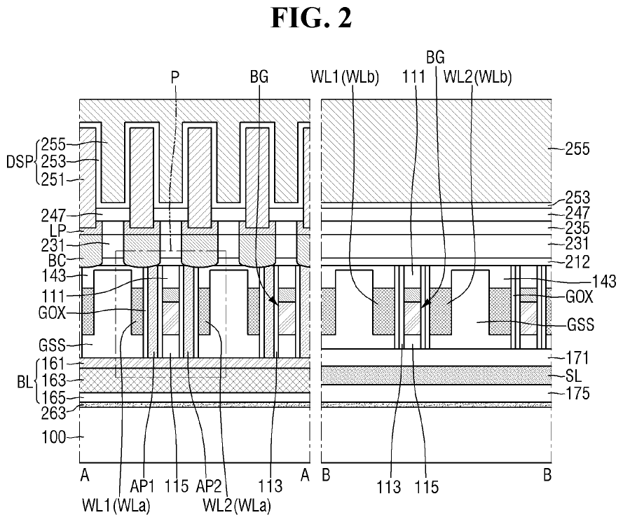

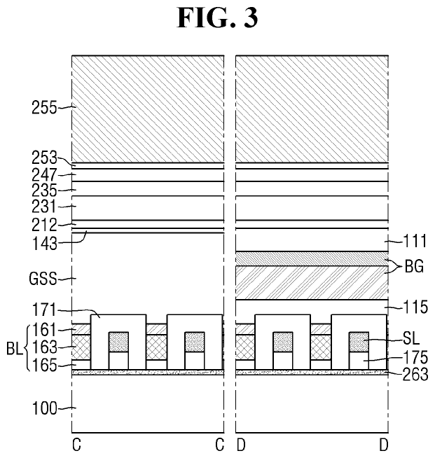

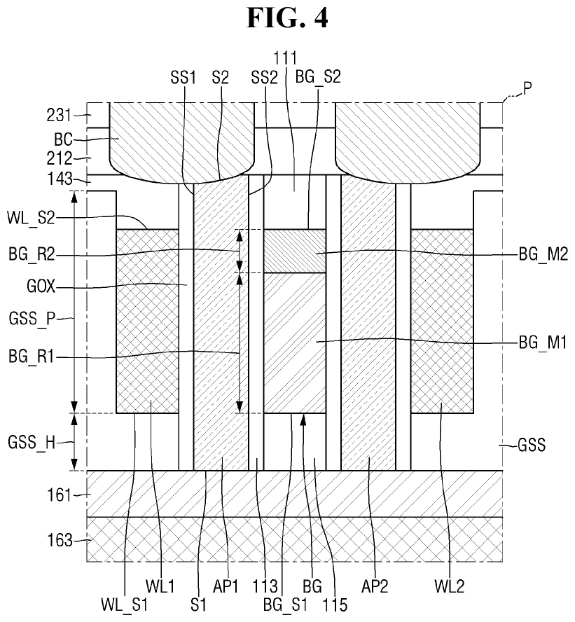

FIG. 1 is a layout view illustrating a semiconductor memory device according to some embodiments. FIG. 2 is a cross-sectional view taken along lines A-A and B-B of FIG. 1. FIG. 3 is a cross-sectional view taken along lines C-C and D-D of FIG. 1. FIG. 4 is an enlarged view illustrating a portion P of FIG. 2.

A semiconductor memory device according to embodiments of the present disclosure may include memory cells that include a vertical channel transistor (VCT).

Referring to FIGS. 1 to 4, a semiconductor memory device according to some embodiments may include bit lines BL, word lines WL1 and WL2, back gate electrodes BG, a shielding conductive line SL, active patterns AP1 and AP2, and data storage patterns DSP.

A substrate 100 may be a silicon substrate, or may include other materials such as silicon germanium, indium antimonide, lead telluride, indium arsenide, indium phosphide, gallium arsenide or gallium antimonide, but is not limited thereto.

Although not shown, the substrate 100 may include a cell array region in which a data storage pattern is arranged, and a peripheral circuit region defined in the periphery of the cell array region.

A bonding insulating layer 263 is on the substrate 100. The bonding insulating layer 263 may be used to bond a wafer. The bonding insulating layer 263 may include, for example, a silicon carbonitride (SiCN).

The bit lines BL may be on the substrate 100. In more detail, the bit lines BL may be on the bonding insulating layer 263.

The bit line BL may be extended to be elongated in a second direction D2. The bit lines BL adjacent to each other may be spaced apart from each other in a first direction D1. The bit line BL includes a long sidewall extended in the second direction D2 and a short sidewall extended in the first direction D1.

Although not shown, each bit line BL may be extended from the cell array region to the peripheral circuit region. An end of each bit line BL may be on the peripheral circuit region.

Each of the bit lines BL may include a semiconductor pattern 161, a metal pattern 163, and a bit line mask pattern 165, which are sequentially stacked. The bit line mask pattern 165 may be in contact with the bonding insulating layer 263. In one variation, the bit line BL may include one of the semiconductor pattern 161 and the metal pattern 163.

The bit line BL may include a conductive bit line. The conductive bit line includes a layer, which is made of a conductive material, of the bit line BL. The conductive bit line may include the semiconductor pattern 161 and the metal pattern 163.

The semiconductor pattern 161 may include a conductive semiconductor material. The semiconductor pattern 161 may include at least one of polysilicon, polysilicon germanium, polygermanium, amorphous silicon, amorphous silicon germanium or amorphous germanium.

The metal pattern 163 may include a conductive material containing a metal. The metal pattern 163 may include at least one of, for example, a conductive metal nitride, a conductive metal silicon nitride, a metal carbonitride, a conductive metal silicide, a conductive metal oxide, a two-dimensional material or a metal.

The bit line mask pattern 165 may include an insulating material, such as a silicon nitride or a silicon oxynitride.

Shielding structures 171, SL and 175 may be on the substrate 100. The shielding structures 171, SL and 175 may be on the bonding insulating layer 263, and may be in contact with the bonding insulating layer 263.

The shielding structures 171, SL and 175 may be adjacent to the bit line BL. The shielding structures 171, SL and 175 may be adjacent to the bit line BL in the first direction D1.

The shielding structures 171, SL and 175 may be between the bit lines BL adjacent to each other in the first direction D1. The shielding structures 171, SL and 175 may be extended in the second direction D2. The shielding structures 171, SL and 175 may be in contact with the bit line BL.

The shielding structure 171, SL and 175 may include a shielding conductive line SL and shielding insulating layers 171 and 175. The shielding insulating layers 171 and 175 may include a shielding insulating liner 171 and a shielding insulating capping layer 175.

The shielding insulating layers 171 and 175 may surround the periphery of the shielding conductive line SL. In other words, the shielding conductive line SL may be inside or between the shielding insulating layers 171 and 175.

The shielding conductive line SL may be extended from the cell array region to the peripheral circuit region. An end of the shielding conductive line SL may be on the peripheral circuit region.

The shielding conductive line SL may include a conductive material. The shielding conductive line SL may include at least one of, for example, a conductive metal nitride, a conductive metal silicon nitride, a metal carbonitride, a conductive metal silicide, a conductive metal oxide, a two-dimensional material or a metal.

Each of the shielding insulating liner 171 and the shielding insulating capping layer 175 may be made of an insulating material. When the shielding insulating liner 171 and the shielding insulating capping layer 175 include the same material, a boundary between the shielding insulating liner 171 and the shielding insulating capping layer 175 may not be distinguished.

Since the shielding structures 171, SL and 175 are between the bit lines BL adjacent to each other in the first direction D1, coupling noise between the bit lines BL may be reduced.

A height of the patterns 161 and 163 in a third direction D3 is shown to be greater than a height of the shielding conductive line SL in the third direction D3, but is not limited thereto. A distance between the bonding insulating layer 263 to the shielding conductive line SL is shown to be greater than a distance between the bonding insulating layer 263 to the metal pattern 163, but is not limited thereto.

The shielding conductive line SL may include a first surface and second surface, which are opposite to each other in the third direction D3. The metal pattern 163 may include a first surface and a second surface, which are opposite to each other in the third direction D3. The first surface of the shielding conductive line SL is closer to the bonding insulating layer 263 than the second surface of the shielding conductive line SL. The first surface of the metal pattern 163 is closer to the bonding insulating layer 263 than the second surface of the metal pattern 163. A distance between the second surface of the shielding conductive line SL and the bonding layer 263 is greater than a distance between the second surface of the metal pattern 163 and the bonding insulating layer 263, but is not limited thereto.

The first surface of the shielding conductive line SL is shown as being planar, but is not limited thereto. In one variation, the first surface of the shielding conductive line SL may be a concave curved surface.

The first active patterns AP1 and the second active patterns AP2 may be on their respective bit lines BL. The first active patterns AP1 and the second active patterns AP2 may be alternately arranged along the second direction D2.

The first active patterns AP1 may be spaced apart from each other in the first direction D1. The first active patterns AP1 may be spaced apart from each other at a predetermined distance. The second active patterns AP2 may be spaced apart from each other in the first direction D1. The second active patterns AP2 may be spaced apart from each other at a predetermined distance. The first and second active patterns AP1 and AP2 may be two-dimensionally arranged along the first direction D1 and the second direction D2, which cross each other.

For example, each of the first active pattern AP1 and the second active pattern AP2 may be made of a single crystalline semiconductor material. As a more specific example, each of the first active pattern AP1 and the second active pattern AP2 may be formed of single crystalline silicon.

Each of the first active pattern AP1 and the second active pattern AP2 may have a length in the first direction D1, have a width in the second direction D2 and have a height in the third direction D3. Each of the first active pattern AP1 and the second active pattern AP2 may have a substantially uniform width. That is, each of the first and second active patterns AP1 and AP2 may have substantially the same width on the first and second surfaces S1 and S2. Also, the width of the first active pattern AP1 may be the same as the width of the second active pattern AP2.

The width of the first active pattern AP1 and the width of the second active pattern AP2 may be several nm to several tens of nm. For example, the width of the first active pattern AP1 and the width of the second active pattern AP2 may be 1 nm to 30 nm, including endpoints, (e.g., 1 nm to 10 nm, including endpoints), but are not limited thereto. The length of each of the first and second active patterns AP1 and AP2 may be greater than a line width of the bit line BL. That is, the length of each of the first and second active patterns AP1 and AP2 may be greater than the width of the bit line BL in the first direction D1.

In FIG. 4, each of the first and second active patterns AP1 and AP2 includes a first surface S1 and a second surface S2, which face each other in the third direction D3. For example, the first surfaces S1 of the first and second active patterns AP1 and AP2 may be in contact with the semiconductor pattern 161 of the bit line BL. In one variation, when the semiconductor pattern 161 is omitted, the first surfaces S1 of the first and second active patterns AP1 and AP2 may be in contact with the metal pattern 163.

Each of the first active pattern AP1 and the second active pattern AP2 may include a first sidewall SS1 and a second sidewall SS2, which face each other in the second direction D2. The second sidewall SS2 of the first active pattern AP1 may face the first sidewall SS1 of the second active pattern AP2.

The first sidewall SS1 of the first active pattern AP1 may be adjacent to the first word line WL1. The second sidewall SS2 of the second active pattern AP2 may be adjacent to the second word line WL2.

Although not shown, for example, each of the first active pattern AP1 and the second active pattern AP2 may include a first dopant region adjacent to the bit line BL and a second dopant region adjacent to a contact pattern BC. Each of the first and second active patterns AP1 and AP2 may include a channel region between the first dopant region and the second dopant region. The first dopant region and the second dopant region are regions doped with dopants in the first active pattern AP1 and the second active pattern AP2. In one variation, each of the first and second active patterns AP1 and AP2 may not include at least one of the first dopant region or the second dopant region.

When the semiconductor memory device operates, the channel regions of the first and second active patterns AP1 and AP2 may be controlled by the first and second word lines WL1 and WL2 and back gate electrodes BG. Since the first and second active patterns AP1 and AP2 are made of a single crystalline semiconductor material, leakage current characteristics of the semiconductor memory device may be improved.

The back gate electrodes BG may be on the bit line BL and the shielding conductive line SL. The back gate electrodes BG may be spaced apart from each other in the second direction D2. The back gate electrodes BG may be spaced apart from each other at a predetermined distance. Each back gate electrode BG may be extended in the first direction D1 across the bit line BL.

Each back gate electrode BG may be between the first active pattern AP1 and the second active pattern AP2, which are adjacent to each other in the second direction D2. In other words, the first active pattern AP1 may be on one side of each back gate electrode BG, and the second active pattern AP2 may be on the other side of each back gate electrode BG. A height of the back gate electrode BG in the third direction D3 may be lower than a height of the first and second active patterns AP1 and AP2.

Each back gate electrode BG may be between the second sidewall SS2 of the first active pattern AP1 and the first sidewall SS1 of the second active pattern AP2. Each back gate electrode BG may be on the second sidewall SS2 of the first active pattern AP1 and the first sidewall SS1 of the second active pattern AP2.

The first active pattern AP1 may be between the first word line WL1 and the back gate electrode BG. The second active pattern AP2 may be between the second word line WL2 and the back gate electrode BG. A pair of the first word line WL1 and the second word line WL2 may be between the back gate electrodes BG adjacent to each other in the second direction D2.

The back gate electrode BG may include a first surface BG_S1 and a second surface BG_S2, which face each other in the third direction D3. The first surface BG_S1 of the back gate electrode is closer to the bit line BL than the second surface BG_S2 of the back gate electrode.

The back gate electrode BG may include a first region BG_R1 containing a first conductive material, and a second region BG_R2 containing a second conductive material. The first conductive material is different from the second conductive material. For example, a work function of the first conductive material may be greater than that of the second conductive material.

The first conductive material may include at least one of a titanium nitride (TiN), tungsten (W) or molybdenum (Mo). The second conductive material may include at least one of, for example, polysilicon doped with n-type impurities, lanthanum oxide (LaO) or titanium aluminum carbide (TiAlC). The first conductive material and the second conductive material, which are described above, are only examples, and are not limited thereto. That is, materials having different work functions may be used as the first conductive material and the second conductive material.

The first region BG_R1 of the back gate electrode may be a first electrode pattern BG_M1. The first electrode pattern BG_M1 may include a first conductive material. For example, the first electrode pattern BG_M1 may be made of the first conductive material.

The second region BG_R2 of the back gate electrode may be a second electrode pattern BG_M2. The second electrode pattern BG_M2 may include a second conductive material. For example, the second electrode pattern BG_M2 may be made of the second conductive material.

In the semiconductor memory device according to some embodiments, the first region BG_R1 of the back gate electrode may be closer to the bit line BL than the second region BG_R2 of the back gate electrode. The first region BG_R1 of the back gate electrode may be between the second region BG_R2 of the back gate electrode and the bit line BL. The first surface BG_S1 of the back gate electrode may be defined by the first electrode pattern BG_M1. The second surface BG_S2 of the back gate electrode may be defined by the second electrode pattern BG_M2.

The back gate electrode BG may block an electric field of a word line that does not operate, thereby improving the reliability of a vertical channel transistor. A voltage may be applied to the back gate electrode BG during operation of the semiconductor memory device to adjust a threshold voltage of the vertical channel transistor. A negative voltage may be applied to the back gate electrode BG to adjust the threshold voltage of the vertical channel transistor. As the negative voltage is applied to the back gate electrode BG, gate induced drain leakage (GIDL) of the vertical channel transistor may be degraded or inhibited. As the back gate electrode BG has a multi-layered structure having different materials, GIDL characteristics of the vertical channel transistor may be improved.

The back gate isolation pattern 111 may be between the first active pattern AP1 and the second active pattern AP2, which are adjacent to each other in the second direction D2. The back gate isolation pattern 111 may be extended in the first direction D1 in parallel with the back gate electrode BG. The back gate isolation pattern 111 may be on the second surface BG_S2 of the back gate electrode BG.

The back gate isolation pattern 111 may be made of an insulating material. The back gate isolation pattern 111 may include, for example, a silicon oxide layer, a silicon oxynitride layer or a silicon nitride layer, but is not limited thereto.

The back gate insulating pattern 113 may be between the back gate electrode BG and the first active pattern AP1 and between the back gate electrode BG and the second active pattern AP2. The back gate insulation pattern 113 may be between the back gate isolation pattern 111 and the first active pattern AP1 and between the back gate isolation pattern 111 and the second active pattern AP2.

The back gate insulating pattern 113 may be made of an insulating material. The back gate insulating pattern 113 may include, for example, a silicon oxide layer, a silicon oxynitride layer, a high dielectric constant insulating layer having a dielectric constant higher than a dielectric constant of the silicon oxide layer, or a combination thereof.

A back gate capping pattern 115 may be between the bit line BL and the back gate electrode BG. The back gate capping pattern 115 may be between the first active pattern AP1 and the second active pattern AP2, which are adjacent to each other in the second direction D2.

The back gate capping pattern 115 may be extended in the first direction D1 in parallel with the back gate electrode BG. The back gate capping pattern 115 may be on the first surface BG_S1 of the back gate electrode. A thickness of the back gate capping pattern 115 between the bit lines BL may be different from a thickness of the back gate capping pattern 115 on the bit line BL.

The back gate capping pattern 115 may be made of an insulating material. The back gate capping pattern 115 may include at least one of, for example, a silicon oxide layer, a silicon oxynitride layer or a silicon nitride layer, but is not limited thereto.

The first word line WL1 and the second word line WL2 may be on the bit line BL and the shielding conductive line SL. Each of the first word line WL1 and the second word line WL2 may be extended in the first direction D1. The first word line WL1 and the second word line WL2 may be alternately disposed in the second direction D2.

The first word line WL1 may be on the first sidewall SS1 of the first active patterns AP1. The second word line WL2 may be on the second sidewall SS2 of the second active patterns AP2. The first active patterns AP1 and the second active patterns AP2 may be between the first word line WL1 and the second word line WL2, which are adjacent to each other in the second direction D2.

The first word line WL1 and the second word line WL2 may be spaced apart from the bit line BL and the contact pattern BC in the third direction D3. The first word line WL1 and the second word line WL2 may be positioned between the bit line BL and the contact pattern BC.

Each of the first word line WL1 and the second word line WL2 may have a width in the second direction D2. The width of the first word line WL1 and the width of the second word line WL2 on the bit line BL may be different from the width of the first word line WL1 and the width of the second word line WL2 on the shielding conductive line SL.

For example, each of the first word line WL1 and the second word line WL2 may include a first portion WLa and a second portion WLb. A width of the first portion WLa in the second direction D2 may be smaller than that of the second portion WLb in the second direction D2. As one example, the first portion WLa may be on the bit line BL. The second portion WLb may be on the shielding conductive line SL.

Each of the first word line WL1 and the second word line WL2 may include a first portion WLa and a second portion WLb, which are alternately arranged along the first direction D1. In the first word line WL1, each of the first active patterns AP1 may be between the second portions WLb adjacent to each other in the first direction D1. In the second word line WL2, each of the second active patterns AP2 may be between the second portions WLb adjacent to each other in the first direction D1.

The first word line WL1 and the second word line WL2 may include a first surface WL_S1 and a second surface WL_S2, which face each other in the third direction D3. The first surface WL_S1 of the first and second word lines is closer to the bit line BL than the second surface WL_S2 of the first and second word lines.

The first word line WL1 will be described by way of example. As an example, a height of the first word line WL1 in the third direction D3 may be the same as the height of the back gate electrode BG in the third direction D3. As another example, a height of the first word line WL1 in the third direction D3 may be greater than the height of the back gate electrode BG in the third direction D3. As another example, a height of the first word line WL1 in the third direction D3 may be less than the height of the back gate electrode BG in the third direction D3.

In addition, for example, the distance between the first surface WL_S1 of the first word line and the bit line BL may be the same as the distance between the first surface BG_S1 of the back gate electrode and the bit line BL. As another example, the distance between the first surface WL_S1 of the first word line and the bit line BL may be greater than the distance between the first surface BG_S1 of the back gate electrode and the bit line BL. As another example, the distance between the first surface WL_S1 of the first word line and the bit line BL may be less than the distance between the first surface BG_S1 of the back gate electrode and the bit line BL.

In addition, for example, the distance between the second surface WL_S2 of the first word line and the bit line BL may be the same as the distance between the second surface BG S2 of the back gate electrode and the bit line BL. As another example, the distance between the second surface WL_S2 of the first word line and the bit line BL may be greater than the distance between the second surface BG_S2 of the back gate electrode and the bit line BL. As another example, the distance between the second surface WL_S2 of the first word line and the bit line BL may be less than the distance between the second surface BG_S2 of the back gate electrode and the bit line BL.

The first word line WL1 and the second word line WL2 may include a conductive material. The first word line WL1 and the second word line WL2 may include at least one of, for example, a doped polysilicon, a conductive metal nitride, a conductive metal silicon nitride, a metal carbonitride, a conductive metal silicide, a conductive metal oxide, a two-dimensional material or a metal.

The first surfaces WL_S1 of the first and second word lines WL1 and WL2 may be planar. In one variation, the first surfaces WL S1 of the first and second word lines WL1 and WL2 may be rounded to be concave. As another example, each of the first word line WL1 and the second word line WL2 may have a spacer shape. In other words, the first surfaces WL S1 of the first and second word lines WL1 and WL2 may be rounded to be convex.

The second surface WL_S2 of the first and second word lines WL1 and WL2 may be planar. In one variation, the second surface WL_S2 of the first and second word lines WL1 and WL2 may have a concave curved surface. The first surface BG_S1 of the back gate electrode and the second surface BG_S2 of the back gate electrode are shown as being planar, but are not limited thereto.

Gate insulating patterns GOX may be between the first word line WL1 and the first active pattern AP1 and between the second word line WL2 and the second active pattern AP2. The gate insulating pattern GOX may be extended in the first direction D1 in parallel with the first word line WL1 and the second word line WL2.

The gate insulating pattern GOX may include a silicon oxide layer, a silicon oxynitride layer, a high dielectric constant insulating layer having a dielectric constant higher than a dielectric constant of the silicon oxide layer or a combination thereof.

The gate insulating pattern GOX may be extended along the first sidewall SS1 of the first active pattern AP1, and may be extended along the second sidewall SS2 of the second active pattern AP2. In the semiconductor memory device according to some embodiments, and in a cross-sectional view, the gate insulating pattern GOX between the first active pattern AP1 and the first word line WL1 may be separated from the gate insulating pattern GOX between the second active pattern AP2 and the second word line WL2.

A gate capping pattern 143 may be between the first word line WL1 and the contact pattern BC and between the second word line WL2 and the contact pattern BC. The gate capping pattern 143 may cover the second surface WL_S2 of the first and second word lines WL1 and WL2.

A gate isolation pattern GSS may be on the bit line BL. The gate isolation pattern GSS may be between the bit line BL and the contact pattern BC. The gate isolation pattern GSS may be in contact with the bit line BL.

The gate isolation pattern GSS may be between the first word line WL1 and the second word line WL2, which are adjacent to each other in the second direction D2. The first word line WL1 and the second word line WL2 may be separated by the gate isolation pattern GSS. The gate isolation pattern GSS may be extended in the first direction D1 between the first word line WL1 and the second word line WL2.

The first word line WL1 may be between the gate isolation pattern GSS and the first active pattern AP1. The second word line WL2 may be between the gate isolation pattern GSS and the second active pattern AP2.

The gate isolation pattern GSS may include a horizontal portion GSS_H and a protrusion portion GSS_P. The protrusion portion GSS_P of the gate isolation pattern may be protruded in the third direction D3 from the horizontal portion GSS_H.

The horizontal portion GSS_H_ of the gate isolation pattern may be closer to the bit line BL than the protrusion portion GSS_P. The horizontal portion GSS_H of the gate isolation pattern may be in contact with the bit line BL. A width of the horizontal portion GSS_H of the gate isolation pattern in the second direction D2 is greater than the width of the protrusion portion GSS_P of the gate isolation pattern in the second direction D2.

The protrusion portion GSS_P of the gate isolation pattern may be between a sidewall of the first word line WL1 and a sidewall of the second word line WL2, which face each other. The horizontal portion GSS_H of the gate isolation pattern may cover the first surface WL_S1 of the first and second word lines WL1 and WL2.

The first word line WL1 and the second word line WL2 are on the horizontal portion GSS_H of the gate isolation pattern. The first word line WL1 and the second word line WL2 may be on the horizontal portion GSS_H of the gate isolation pattern. The first word line WL1 and the second word line WL2 may be between the horizontal portion GSS_H of the gate isolation pattern and the contact pattern BC.

The gate isolation pattern GSS may be made of an insulating material. In one variation, the gate isolation pattern GSS may include a plurality of insulating layers.

The contact patterns BC may pass through a contact interlayer insulating layer 231 and a contact etching stop layer 212. The contact patterns BC may be connected to the first active pattern AP1 and the second active pattern AP2, respectively. The contact patterns BC may be connected to the second surface S2 of the first and second active patterns AP1 and AP2. Each of the contact patterns BC may have various shapes, such as a circular shape, an oval shape, a rectangular shape, a square shape, a rhombus shape and a hexagonal shape.

The contact pattern BC may include a conductive material. The contact pattern BC may include at least one of, for example, a doped polysilicon, a conductive metal nitride, a conductive metal silicon nitride, a metal carbonitride, a conductive metal silicide, a conductive metal oxide, a two-dimensional material or a metal.

The contact etching stop layer 212 may be on the gate capping pattern 143 and the back gate isolation pattern 111. Each of the contact interlayer insulating layer 231 and the contact etching stop layer 212 may be made of an insulating material.

Landing pads LP may be on the contact pattern BC. In view of a plane, the landing pads LP may have various shapes such as a circular shape, an oval shape, a rectangular shape, a square shape, a rhombus shape and a hexagonal shape.

Pad isolation insulating patterns 235 may be between the landing pads LP. In view of a plane, the landing pads LP may be arranged in the form of a matrix along the first direction D1 and the second direction D2. An upper surface of the landing pad LP may be substantially coplanar with an upper surface of the pad isolation insulating pattern 235.

The landing pad LP includes a conductive material, and may include at least one of, for example, a doped polysilicon, a conductive metal nitride, a conductive metal silicon nitride, a metal carbonitride, a conductive metal silicide, a conductive metal oxide, a two-dimensional material or a metal.

The data storage patterns DSP may be on the landing pads LP, respectively. The data storage patterns DSP may be electrically connected to the first and second active patterns AP1 and AP2, respectively. As shown in FIG. 1, the data storage patterns DSP may be arranged in the form of a matrix along the first direction D1 and the second direction D2. The data storage patterns DSP may completely or partially overlap the landing pads LP in the third direction D3. The data storage patterns DSP may be in contact with all or some of the upper surface of the landing pads LP.

As an example, the data storage patterns DSP may be capacitors. The data storage patterns DSP may include a capacitor dielectric layer 253 interposed between a storage electrode 251 and a plate electrode 255. In one embodiment, the storage electrode 251 may be in contact with the landing pad LP. In view of a plane, the storage electrode 251 may have various shapes, such as a circular shape, an oval shape, a rectangular shape, a square shape, a rhombus shape and a hexagonal shape. The data storage patterns DSP may completely or partially overlap the landing pads LP. The data storage patterns DSP may be in contact with all or some of the upper surface of the landing pads LP. The storage electrode 251 may pass through the upper etching stop layer 247. The upper etching stop layer 247 may be made of an insulating material.

Alternatively, the data storage patterns DSP may be variable resistance patterns that may be switched to two types of resistance states by an electrical pulse applied to a memory element. For example, the data storage patterns DSP may include a phase-change material in which a crystal state is changed depending on the amount of a current, perovskite compounds, a transition metal oxide, magnetic materials, ferromagnetic materials or antiferromagnetic materials.

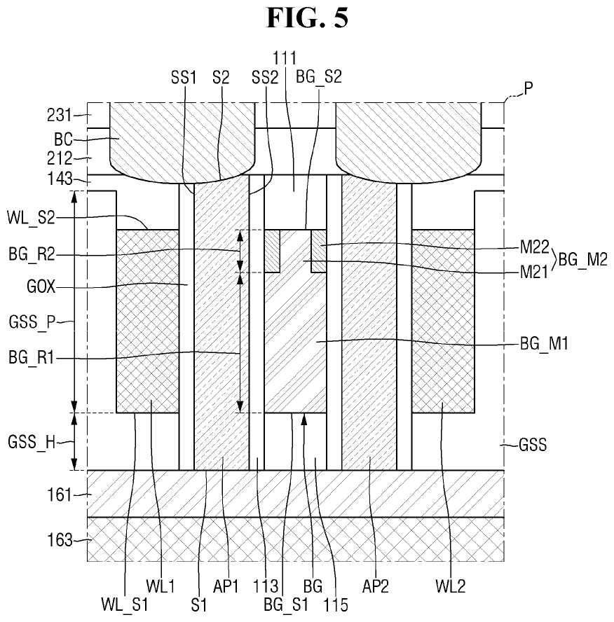

FIGS. 5 to 7 are views illustrating a semiconductor memory device according to some embodiments. For convenience of description, the following description will be based on differences from those described with reference to FIGS. 1 to 4. FIGS. 5 to 7 are enlarged views illustrating a portion P of FIG. 2.

Referring to FIGS. 5 to 7, in the semiconductor memory device according to some embodiments, a second electrode pattern BG_M2 may include a first sub-electrode pattern M21 and a second sub-electrode pattern M22.

The second sub-electrode pattern M22 may include a second conductive material. For example, the second sub-electrode pattern M22 may be made of the second conductive material.

For example, the first sub-electrode pattern M21 may include a first conductive material. The first sub-electrode pattern M21 may be made of the first conductive material. The first sub-electrode pattern M21 may include the same material as the first electrode pattern BG_M1.

In another example, the first sub-electrode pattern M21 may include a material different from that of the first electrode pattern BG_M1. In this embodiment, a work function of the conductive material included in the first sub-electrode pattern M21 may be greater than a work function of the second conductive material.

In FIG. 5, the second sub-electrode pattern M22 may include a pair of vertical portions extended in the third direction D3. The second sub-electrode patterns M22 may be spaced apart from each other in the second direction D2. For example, the second sub-electrode patterns M22 may have a pair of bar shapes. The second sub-electrode pattern M22 having the bar shape may be extended to be elongated in the first direction D1.

The first sub-electrode pattern M21 may be between the second sub-electrode patterns M22 spaced apart from each other in the second direction D2. The first sub-electrode pattern M21 may be directly connected to the first electrode pattern BG_M1.

The first region BG_R1 of the back gate electrode and the second region BG_R2 of the back gate electrode may be distinguished from each other based on the second sub-electrode pattern M22. The second surface BG_S2 of the back gate electrode may be defined by the first sub-electrode pattern M21 and the second sub-electrode pattern M22.

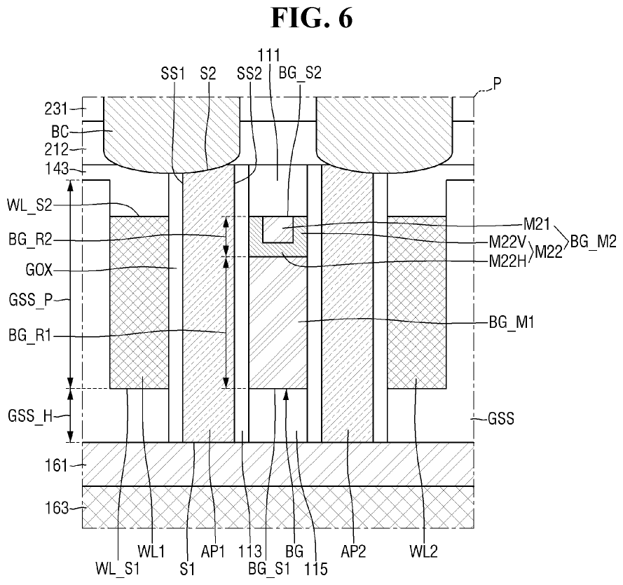

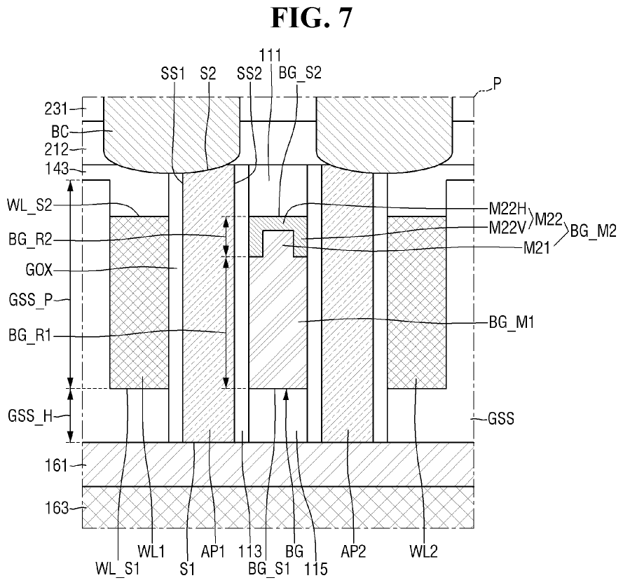

In FIGS. 6 and 7, the second sub-electrode pattern M22 may include a vertical portion M22V and a horizontal portion M22H. The vertical portion M22V of the second sub-electrode pattern is extended in the third direction D3. The horizontal portion M22H of the second sub-electrode pattern may be extended in the second direction D2. The horizontal portion M22H of the second sub-electrode pattern may connect the vertical portions M22V of the second sub-electrode pattern, which are spaced apart from each other in the second direction D2.

In FIG. 6, the horizontal portion M22H of the second sub-electrode pattern may be between the first electrode pattern BG_M1 and the first sub-electrode pattern M21. The first electrode pattern BG_M1 may not be in contact with the first sub-electrode pattern M21. The second surface BG_S2 of the back gate electrode may be defined by the first sub-electrode pattern M21 and the second sub-electrode pattern M22.

In FIG. 7, the first sub-electrode pattern M21 may be directly connected to the first electrode pattern BG_M1. The second surface BG_S2 of the back gate electrode may be defined by the second sub-electrode pattern M22.

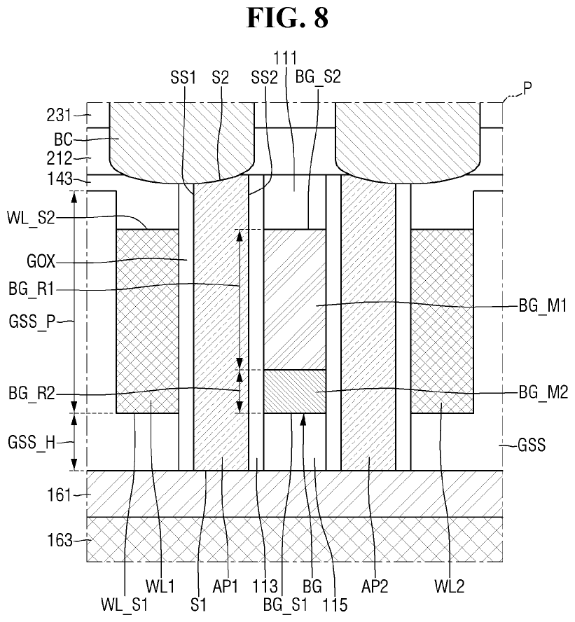

FIGS. 8 to 10 are views illustrating a semiconductor memory device according to some embodiments. The following description will be based on differences from those described with reference to FIGS. 1 to 4. FIGS. 8 to 10 are enlarged views illustrating a portion P of FIG. 2.

Referring to FIGS. 8 to 10, the second region BG_R2 of the back gate electrode may be closer to the bit line BL than the first region BG_R1 of the back gate electrode.

The second region BG_R2 of the back gate electrode may be between the first region BG_R1 of the back gate electrode and the bit line BL. The first surface BG_S1 of the back gate electrode may be defined by the second electrode pattern BG_M2. The second surface BG S2 of the back gate electrode may be defined by the first electrode pattern BG_M1.

In FIG. 8, the first electrode pattern BG_M1 may be made of a first conductive material. The second electrode pattern BG_M2 may be made of a second conductive material.

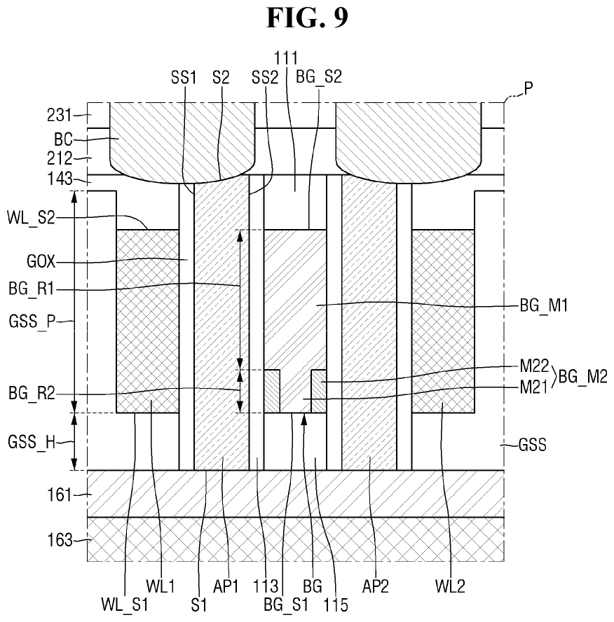

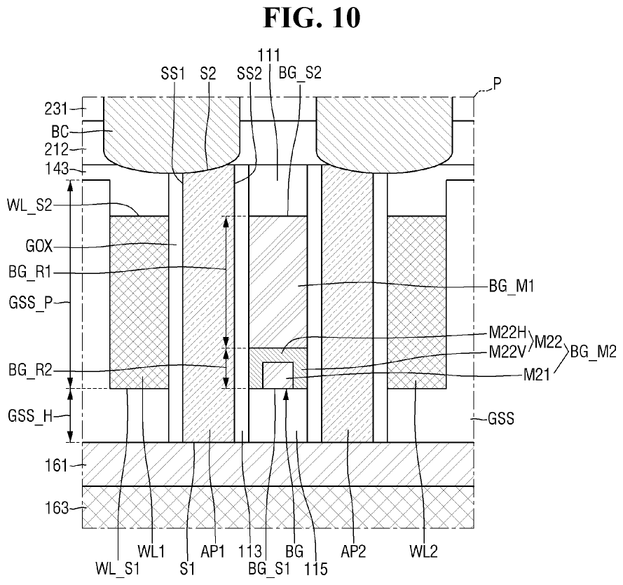

In FIGS. 9 and 10, the second electrode pattern BG_M2 may include a first sub-electrode pattern M21 and a second sub-electrode pattern M22. The second sub-electrode pattern M22 may include a second conductive material. For example, the second sub-electrode pattern M22 may be made of the second conductive material.

For example, the first sub-electrode pattern M21 may include a first conductive material. The first sub-electrode pattern M21 may be made of the first conductive material. The first sub-electrode pattern M21 may include the same material as that of the first electrode pattern BG_M1.

For another example, the first sub-electrode pattern M21 may include a material different from that of the first electrode pattern BG_M1. In this case, a work function of the conductive material included in the first sub-electrode pattern M21 may be greater than the work function of the second conductive material.

In FIG. 9, the second sub-electrode pattern M22 may include a pair of vertical portions extended in the third direction D3. The first sub-electrode pattern M21 may be between the second sub-electrode patterns M22 spaced apart from each other in the second direction D2. The first sub-electrode pattern M21 may be directly connected to the first electrode pattern BG_M1. The first surface BG_S1 of the back gate electrode may be defined by the first sub-electrode pattern M21 and the second sub-electrode pattern M22.

In FIG. 10, the second sub-electrode pattern M22 may include a vertical portion M22V and a horizontal portion M22H. The horizontal portion M22H of the second sub-electrode pattern may connect the vertical portions M22V of the second sub-electrode pattern, which are spaced apart from each other in the second direction D2. The horizontal portion M22H of the second sub-electrode pattern may be between the first electrode pattern BG_M1 and the first sub-electrode pattern M21. The first surface BG_S1 of the back gate electrode may be defined by the first sub-electrode pattern M21 and the second sub-electrode pattern M22.

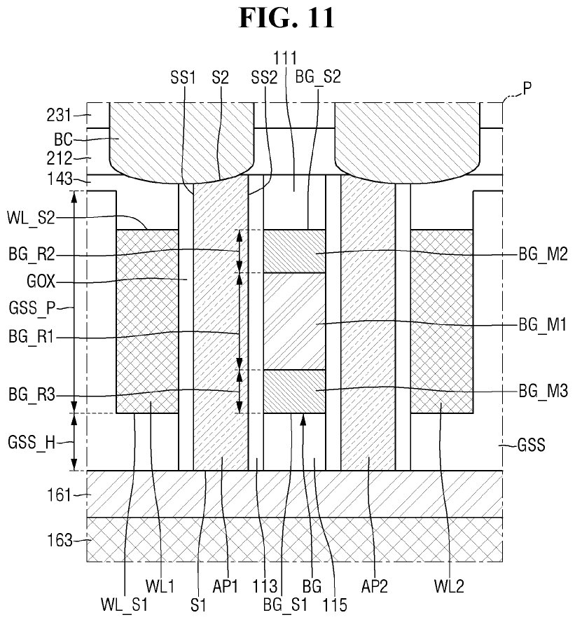

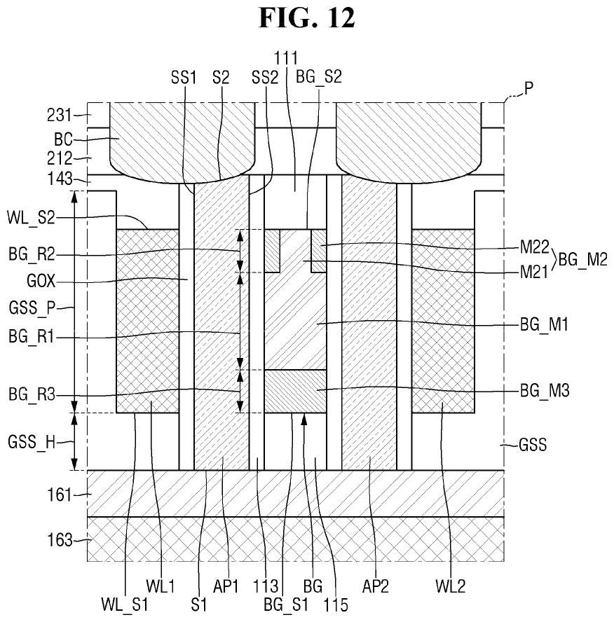

FIGS. 11 and 12 are views illustrating a semiconductor memory device according to some embodiments. For convenience of description, the following description will be based on differences from those described with reference to FIGS. 1 to 5. FIGS. 11 and 12 are enlarged views illustrating a portion P of FIG. 2.

Referring to FIG. 11 and FIG. 12, in the semiconductor memory device according to some embodiments, the back gate electrode BG may further include a third region BG_R3 containing a third conductive material.

The first region BG_R1 of the back gate electrode may be between the second region BG_R2 of the back gate electrode and the third region BG_R3 of the back gate electrode.

The third conductive material is different from the first conductive material. For example, the work function of the first conductive material may be greater than the work function of the third conductive material. For example, the third conductive material may be the same as the second conductive material. As another example, the third conductive material may be different from the second conductive material.

The third region BG_R3 of the back gate electrode may be a third electrode pattern BG M3. The first surface BG_S1 of the back gate electrode may be defined by the third electrode pattern BG_M3. The third electrode pattern BG_M3 may include a third conductive material. For example, the third electrode pattern BG_M3 may be made of the third conductive material.

In one variation, the second electrode pattern BG_M2 of FIGS. 11 and 12 may have a shape similar to the shape of the second electrode pattern BG_M2 shown in FIGS. 6 and 7. Also, the third electrode pattern BG_M3 of FIGS. 11 and 12 may have a shape similar to the shape of the second electrode pattern BG_M2 shown in FIGS. 9 and 10.

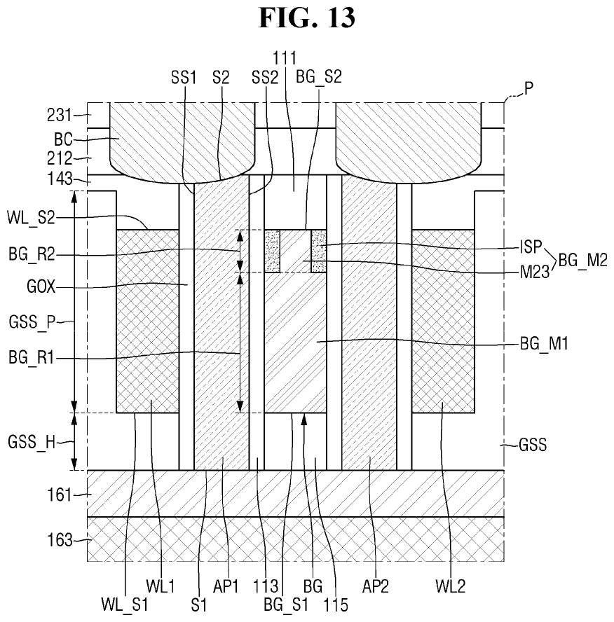

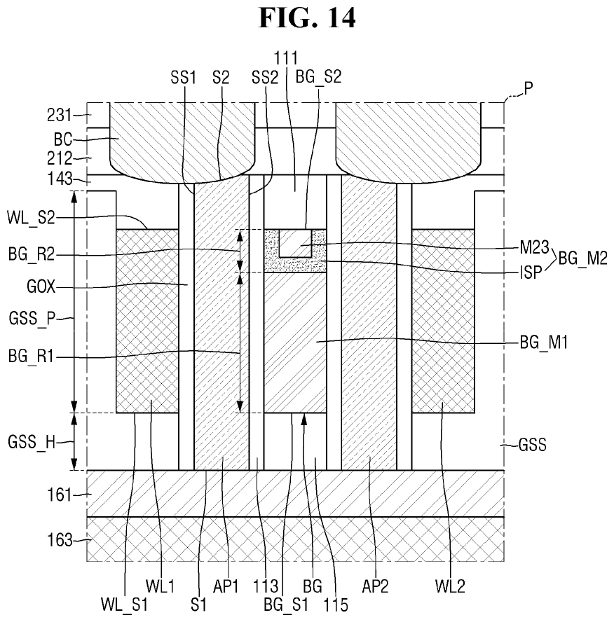

FIGS. 13 and 14 are views illustrating a semiconductor memory device according to some embodiments. For convenience of description, the following description will be based on differences from those described with reference to FIGS. 1 to 4. FIGS. 13 and 14 are enlarged views illustrating a portion P of FIG. 2.

Referring to FIGS. 13 and 14, in the semiconductor memory device according to some embodiments, the second electrode pattern BG_M2 may include a third sub-electrode pattern M23 and an insulating liner ISP.

For example, the third sub-electrode pattern M23 may include a first conductive material. The third sub-electrode pattern M23 may be made of the first conductive material. The third sub-electrode pattern M21 may include the same material as the first electrode pattern BG_M1.

For another example, the third sub-electrode pattern M23 may include a third conductive material different from the first conductive material.

The insulating liner ISP may include an insulating material. For example, the insulating liner ISP may be made of the insulating material.

In FIG. 13, the insulating liner ISP may include a pair of vertical portions extended in the third direction D3. The insulating liners ISP may be spaced apart from each other in the second direction D2. The insulating liner ISP having a bar shape may be extended to be elongated in the first direction D1.

The third sub-electrode pattern M23 may be between the insulating liners ISP spaced apart from each other in the second direction D2. The third sub-electrode pattern M23 may be directly connected to the first electrode pattern BG_M1.

In FIG. 14, the insulating liner ISP may include a vertical portion extended in the third direction D3 and a horizontal portion extended in the second direction D2. The insulating liner ISP may separate the third sub-electrode pattern M23 from the first electrode pattern BG_M1. For example, the third sub-electrode pattern M23 may be in a floating state in which a voltage is not connected. As another example, the same voltage as that applied to the first electrode pattern BG_M1 may be applied to the third sub-electrode pattern M23. A voltage different from that applied to the first electrode pattern BG_M1 may be applied to the third sub-electrode pattern M23.

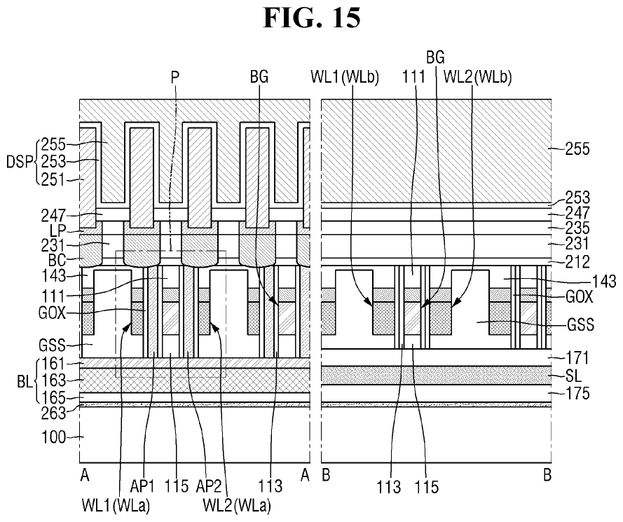

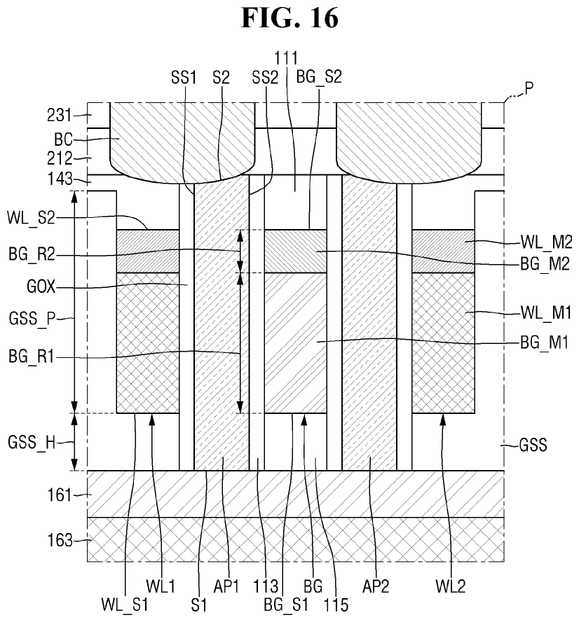

FIGS. 15 and 16 are views illustrating a semiconductor memory device according to some embodiments. For convenience of description, the following description will be based on differences from those described with reference to FIGS. 1 to 4. FIG. 16 is an enlarged view illustrating a portion P of FIG. 15.

Referring to FIGS. 15 and 16, in the semiconductor memory device according to some embodiments, the first word line WL1 and the second word line WL2 may include a first word line material layer WL_M1 and a second word line material layer WL_M2, respectively.

The first word line material layer WL_M1 may include a fourth conductive material. The second word line material layer WL_M2 may include a fifth conductive material that is different from the fourth conductive material. For example, a work function of the fourth conductive material may be different from than the work function of the fifth conductive material.

The first word line WL1 and the second word line WL2 include materials having different work functions, so that the threshold voltage of the vertical channel transistor may be adjusted.

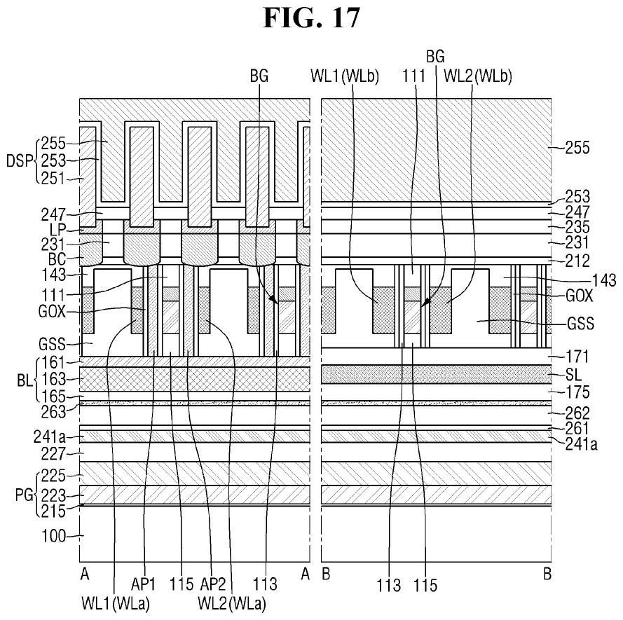

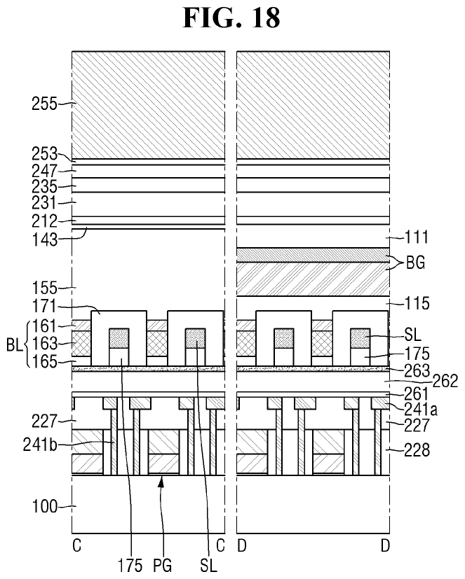

FIGS. 17 and 18 are views illustrating a semiconductor memory device according to some embodiments. For convenience of description, the following description will be based on differences from those described with reference to FIGS. 1 to 4.

Referring to FIGS. 17 and 18, the semiconductor memory device according to some embodiments may further include a peripheral gate structure PG between the substrate 100 and the bit line BL.

The peripheral gate structure PG may be on the substrate 100. The substrate 100 may include a cell array region and a peripheral circuit region. The peripheral gate structure PG may be over the cell array region and the peripheral circuit region. In other words, a portion of the peripheral gate structure PG may be in the cell array region of the substrate 100, and the other portion of the peripheral gate structure PG may be in the peripheral circuit region of the substrate 100.

The peripheral gate structure PG may be included in a sensing transistor, a transfer transistor, a driving transistor, and the like. The types of transistors disposed in the cell array region and the peripheral circuit region may vary depending on design and arrangement of the semiconductor memory device.

The peripheral gate structure PG may include a peripheral gate insulating layer 215, a peripheral lower conductive pattern 223, and a peripheral upper conductive pattern 225. The peripheral gate insulating layer 215 may include a silicon oxide layer, a silicon oxynitride layer, a high dielectric constant insulating layer having a dielectric constant higher than a dielectric constant of the silicon oxide layer, or a combination thereof. The high dielectric constant insulating layer may include at least one of, for example, a metal oxide, a metal oxynitride, a metal silicon oxide or a metal silicon oxynitride, but is not limited thereto.

Each of the peripheral lower conductive pattern 223 and the peripheral upper conductive pattern 225 may include a conductive material. For example, the peripheral lower conductive pattern 223 and the peripheral upper conductive pattern 225 may include at least one of a doped semiconductor material, a conductive metal nitride, a conductive metal silicon nitride, a metal carbonitride, a conductive metal silicide, a conductive metal oxide, a two-dimensional (2D) material, a metal or a metal alloy. The peripheral gate structure PG is shown as including a plurality of conductive patterns, but is not limited thereto.

In the semiconductor memory device according to some embodiments, the two-dimensional material may be a metallic material and/or a semiconductor material. The two-dimensional (2D) material may include a two-dimensional allotrope or a two-dimensional compound, and may include at least one of, for example, graphene, molybdenum disulfide (MoS2), molybdenum diselenide (MoSe2), tungsten diselenide (WSe2), or tungsten disulfide (WS2), but is not limited thereto. That is, since the two-dimensional materials described above are only examples, the two-dimensional material that may be included in the semiconductor memory device of the present disclosure is not limited by the above-described materials.

A first peripheral lower insulating layer 227 and a second peripheral lower insulating layer 228 are on the substrate 100. Each of the first peripheral lower insulating layer 227 and the second peripheral lower insulating layer 228 may be made of an insulating material.

A peripheral wiring line 241a and a peripheral contact plug 241b may be in the first peripheral lower insulating layer 227 and the second peripheral lower insulating layer 228. Although the peripheral wiring line 241a and the peripheral contact plug 241b are shown as being films different from each other, the present disclosure is not limited thereto. A boundary between the peripheral wiring line 241a and the peripheral contact plug 241b may not be distinguished. Each of the peripheral wiring line 241a and the peripheral contact plug 241b includes a conductive material.

A first peripheral upper insulating layer 261 and a second peripheral upper insulating layer 262 may be on the peripheral wiring line 241a and the peripheral contact plug 241b. Each of the first peripheral upper insulating layer 261 and the second peripheral upper insulating layer 262 may be made of an insulating material. In one variation, a peripheral upper insulating layer made of a single layer may be on the peripheral wiring line 241a and the peripheral contact plug 241b.

The bonding insulating layer 263 may be on the second peripheral upper insulating layer 262. The bit line BL and the shielding conductive line SL may be on the peripheral gate structure PG.

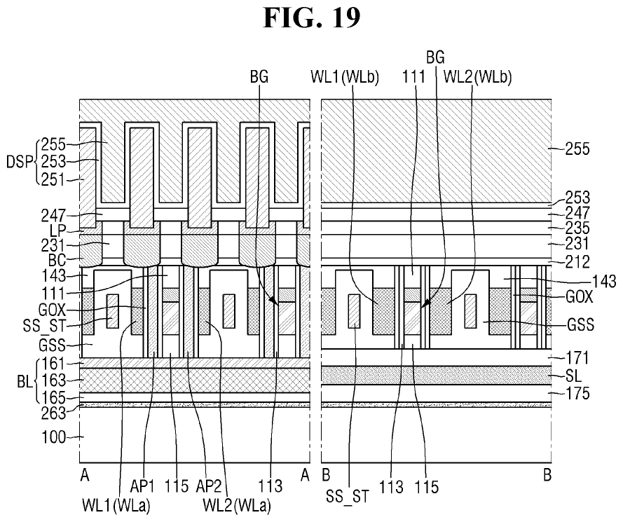

FIGS. 19 to 23 are views illustrating a semiconductor memory device according to some embodiments. For convenience of description, the following description will be based on differences from those described with reference to FIGS. 1 to 18.

Referring to FIG. 19, the semiconductor memory device according to some embodiments may further include an intermediate structure SS_ST between first and second word lines WL1 and WL2 adjacent to each other.

The intermediate structure SS_ST may be extended in the first direction D1 in parallel with the first and second word lines WL1 and WL2. The intermediate structure SS_ST may reduce coupling noise between the first word line WL1 and the second word line WL2, which are adjacent to each other.

The intermediate structure SS_ST may be an air gap surrounded by the gate isolation pattern GSS. Alternatively, the intermediate structure SS_ST may be a shielding line made of a conductive material.

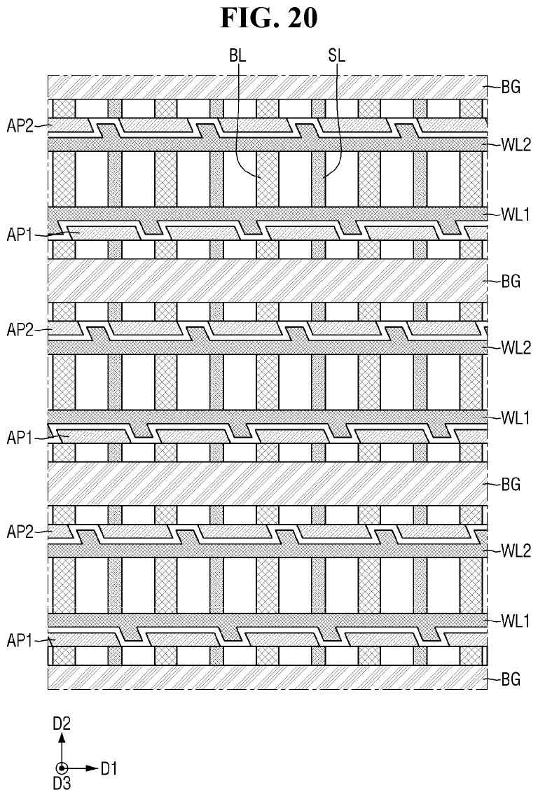

Referring to FIG. 20, in the semiconductor memory device according to some embodiments, the first and second active patterns AP1 to AP2 may be alternately arranged in a diagonal direction with respect to the first direction D1 and the second direction D2. In this case, the diagonal direction may be parallel with the upper surface of the substrate 100.

In view of a plane, each of the first and second active patterns AP1 and AP2 may have a parallelogram shape or a rhombus shape. Since the first and second active patterns AP1 and AP2 are arranged in the diagonal direction, coupling between the first and second active patterns AP1 and AP2 facing each other in the second direction D2 may be reduced.

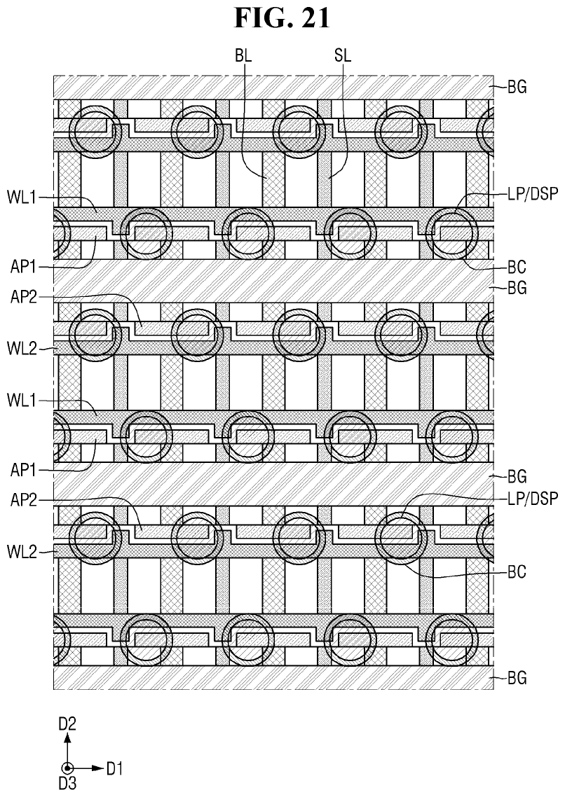

Referring to FIG. 21, in the semiconductor memory device according to some embodiments, the landing pads LP and the data storage patterns DSP may be arranged in a zigzag shape or a honeycomb shape in view of a plane.

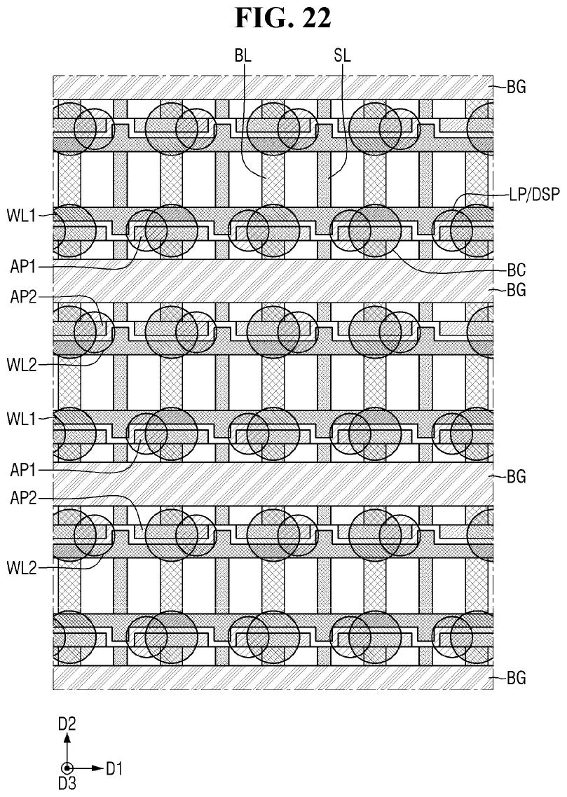

Referring to FIG. 22, in the semiconductor memory device according to some embodiments, the data storage patterns DSP may be misaligned with the landing pads LP in view of a plane.

Each data storage pattern DSP may be in contact with a portion of the landing pad LP.

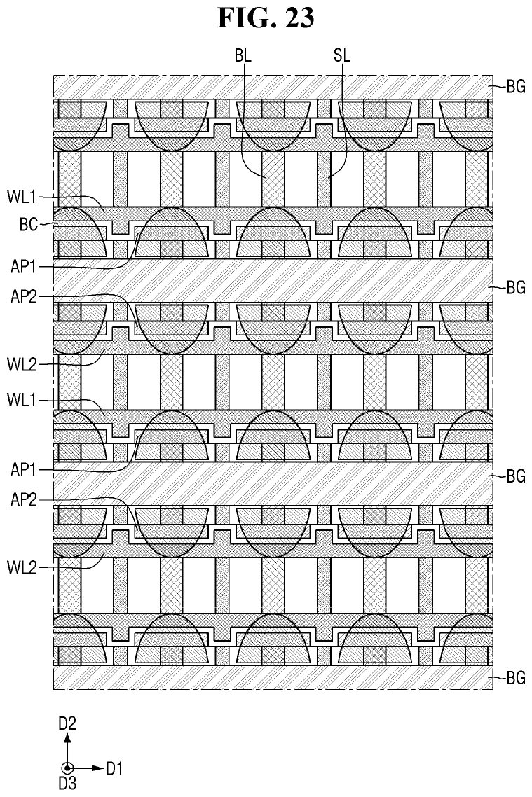

Referring to FIG. 23, in the semiconductor memory device according to some embodiments, each of the contact patterns BC on the first and second active patterns AP1 and AP2 may have a semi-circular shape or a semi-oval shape in view of a plane.

In view of a plane, the contact patterns BC may be symmetric with each other with the back gate electrode BG interposed therebetween.

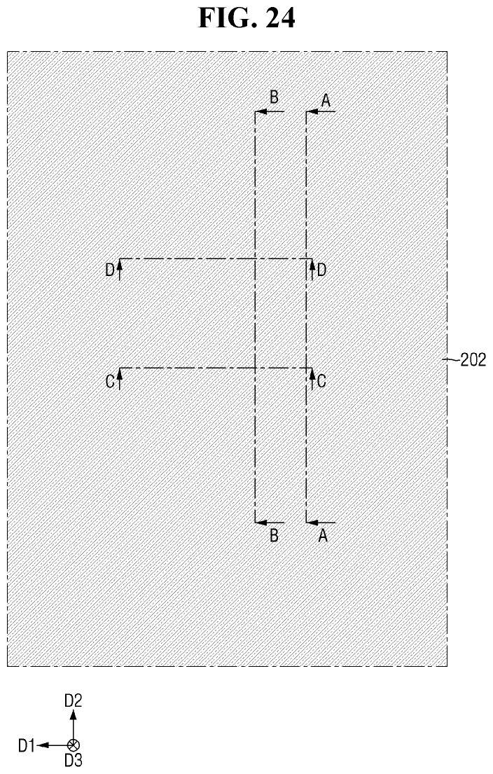

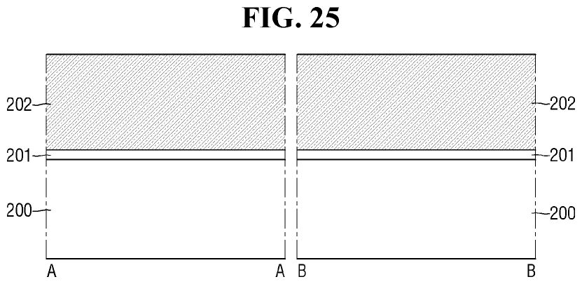

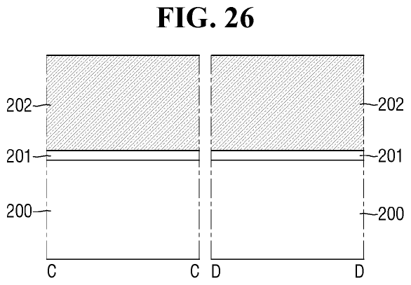

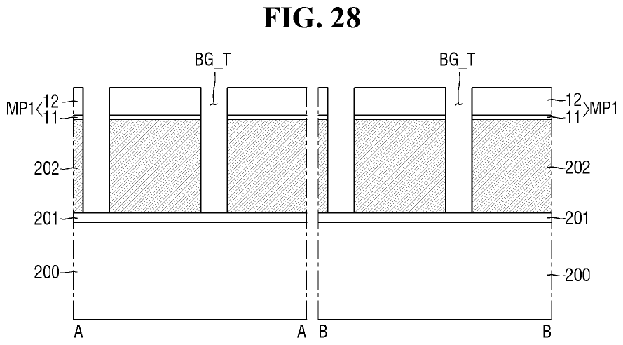

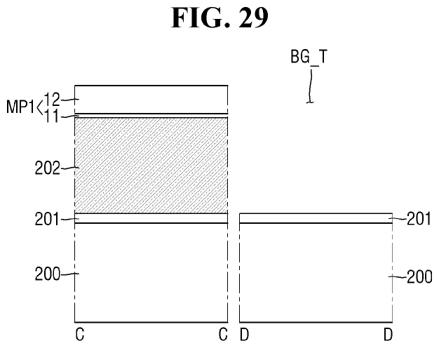

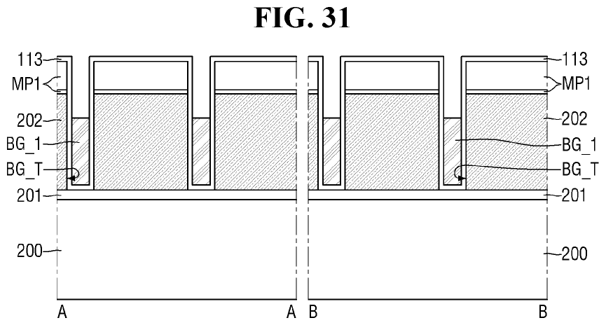

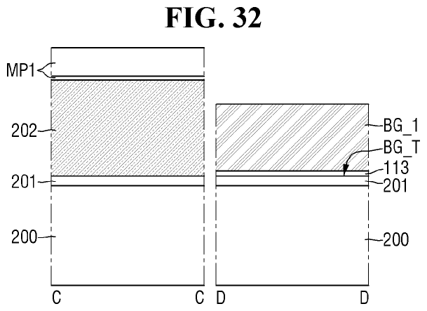

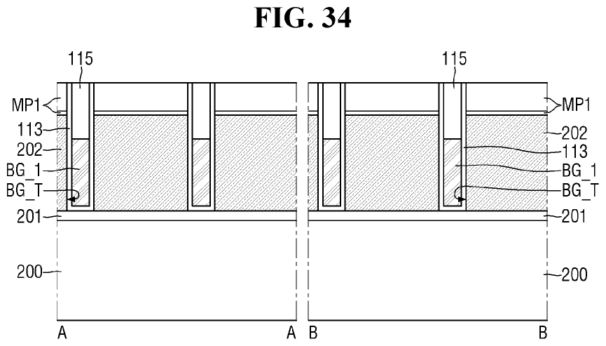

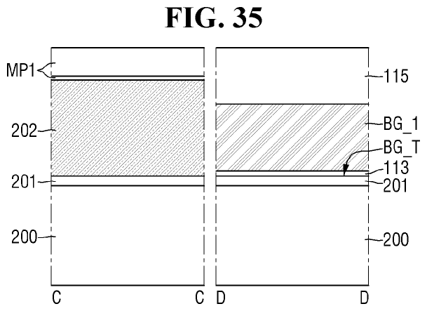

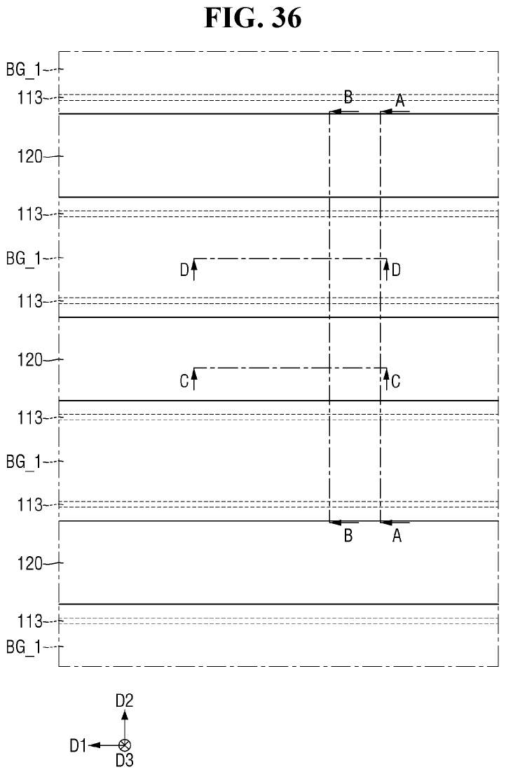

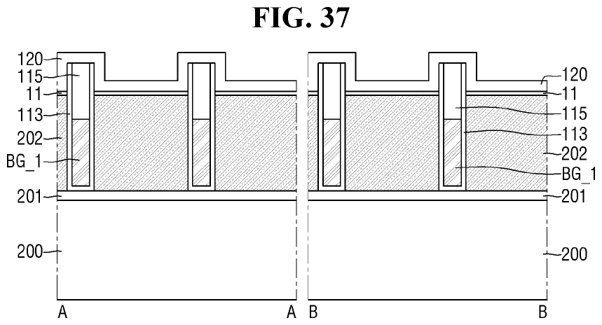

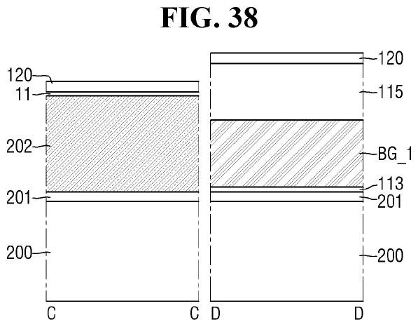

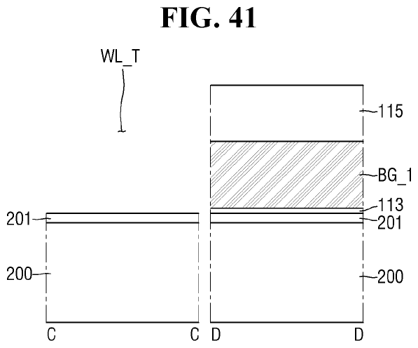

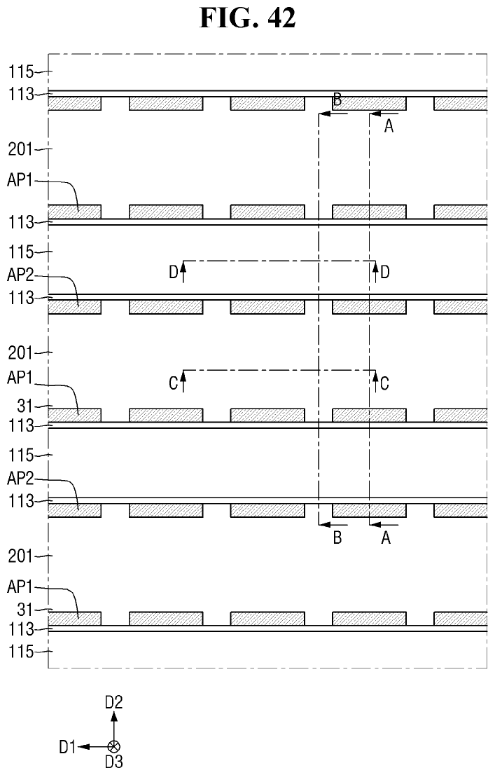

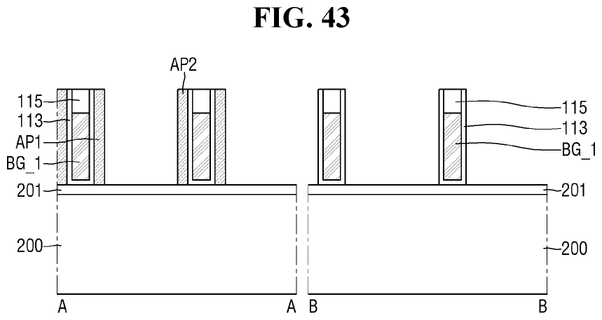

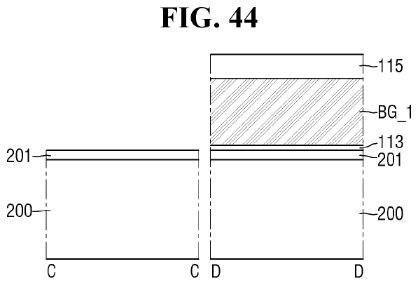

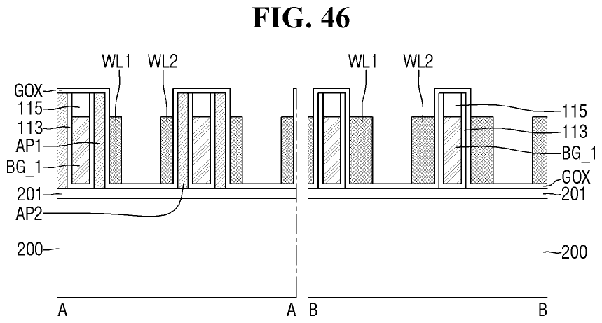

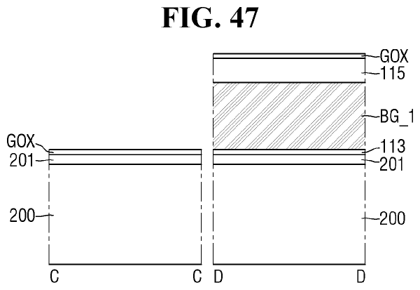

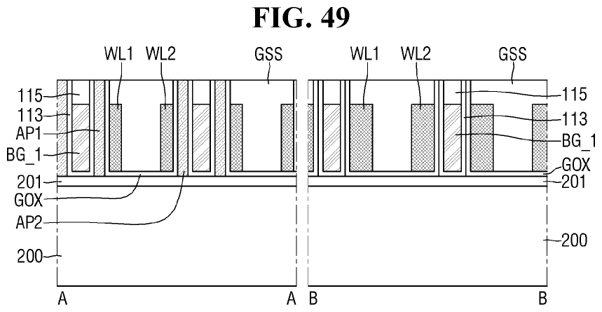

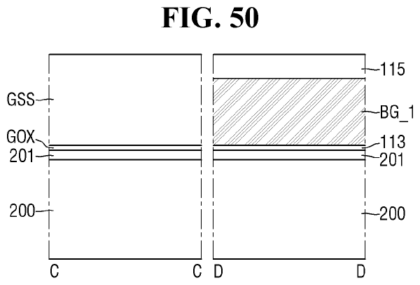

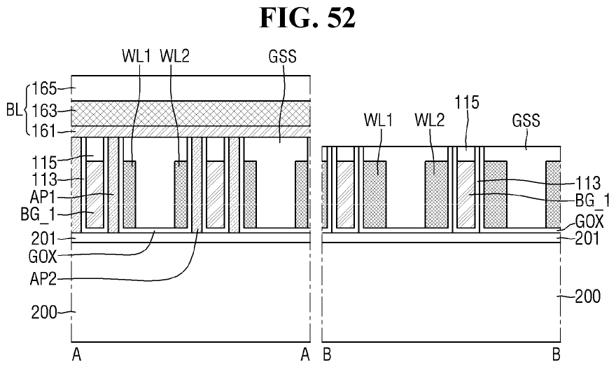

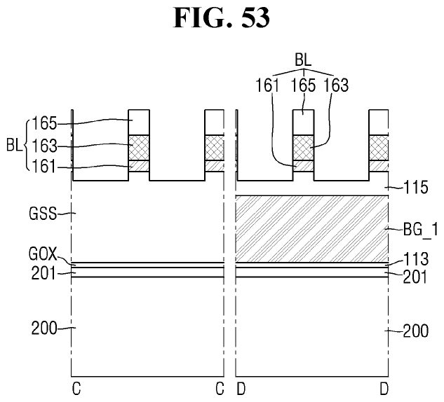

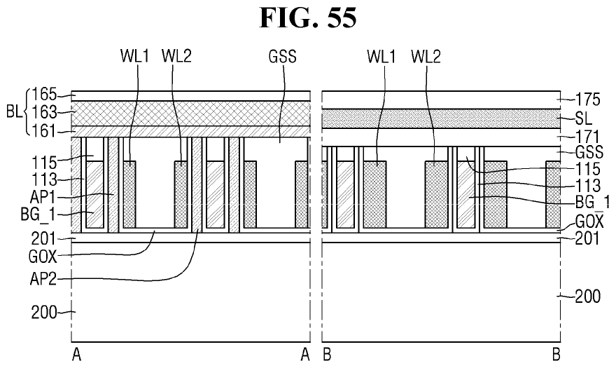

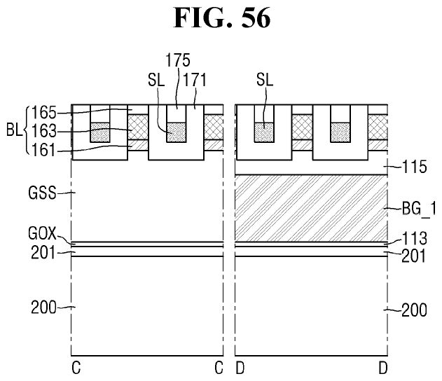

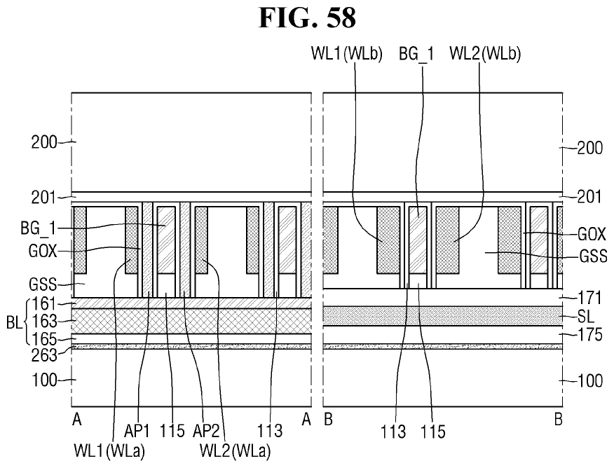

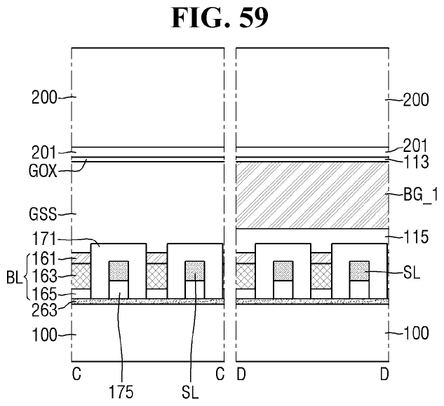

FIGS. 24 to 63 are views illustrating a method for manufacturing a semiconductor memory device according to some embodiments. The semiconductor memory device described with reference to FIGS. 1 to 4 may be manufactured through the method shown in FIGS. 24 to 63.

For reference, a cutting line and a coordinate system, which are shown in FIGS. 24 to 56, are in a state such that a cutting line and a coordinate system of FIG. 1 are inverted in the first direction D1.

Referring to FIGS. 24 to 26, a sub-substrate structure, which includes a sub-substrate 200, a buried insulating layer 201 and an active layer 202, may be provided.

The buried insulating layer 201 and the active layer 202 may be provided on the sub-substrate 200. The sub-substrate 200, the buried insulating layer 201 and the active layer 202 may be a silicon-on-insulator substrate (i.e., SOI substrate). The sub-substrate 200 may be, for example, a silicon substrate, a germanium substrate and/or a silicon-germanium substrate.

The buried insulating layer 201 may be a buried oxide (BOX) formed by separation by implanted oxygen (SIMOX) method or a bonding and layer transfer method. Alternatively, the buried insulating layer 201 may be an insulating layer formed by a chemical vapor deposition method. The buried insulating layer 201 may include, for example, a silicon oxide layer, a silicon nitride layer, a silicon oxynitride layer and/or a low dielectric constant insulating layer.

The active layer 202 may be a single crystalline semiconductor layer. The active layer 202 may be, for example, a single crystalline silicon substrate, a germanium substrate and/or a silicon-germanium substrate. The active layer 202 may have a first surface and a second surface, which are opposite to each other in the third direction D3, and the second surface of the active layer 202 may be in contact with the buried insulating layer 201.

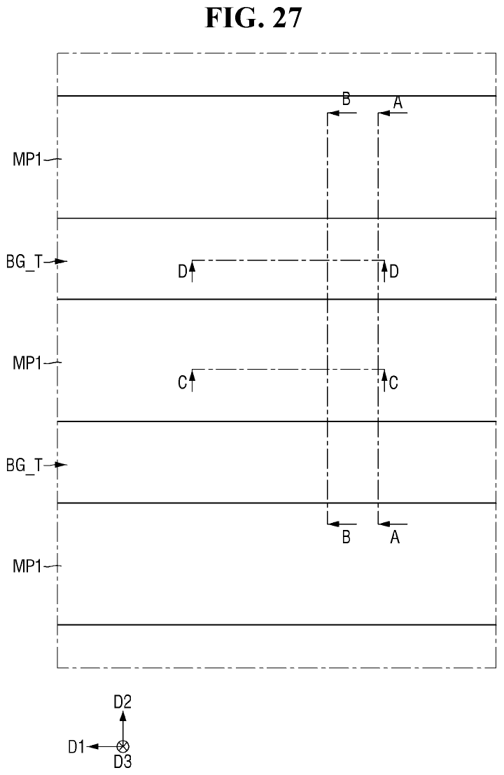

Referring to FIGS. 27 to 29, a back gate mask pattern MP1 may be formed on the active layer 202.

The back gate mask pattern MP1 may have line-shaped openings extended along the first direction D1. The back gate mask pattern MP1 may include a first lower mask layer 11 and a first upper mask layer 12, which are sequentially stacked. The first upper mask layer 12 may be formed of a material having an etching selectivity with respect to the first lower mask layer 11.

For example, the first lower mask layer 11 may include a silicon oxide and the first upper mask layer 12 may include a silicon nitride, but the present disclosure is not limited thereto.

The active layer 202 may be anisotropically etched using the back gate mask pattern MP1 as an etching mask. Therefore, back gate trenches BG_T extended in the first direction D1 may be formed in the active layer 202. The back gate trenches BG_T may expose the buried insulating layer 201, and may be spaced apart from each other at a predetermined distance in the second direction D2.

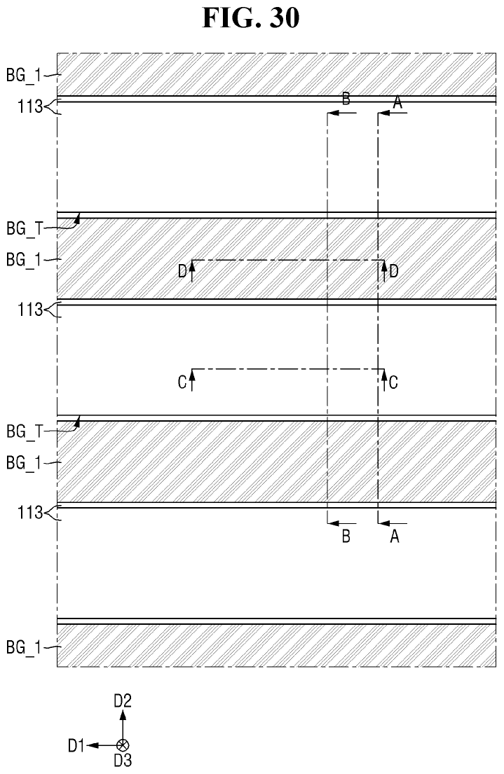

Referring to FIGS. 30 to 32, a back gate insulating pattern 113 and pre-back gate electrodes BG_1 may be formed in the back gate trench BG_T.

In more detail, the back gate insulating pattern 113 may be formed along sidewalls and a bottom surface of the back gate trench BG_T and an upper surface of the back gate mask pattern MP1. A back gate conductive layer may be formed on the back gate insulating pattern 113. The back gate conductive layer may fill the back gate trench BG_T. Then, the back gate conductive layer may be isotropically etched to form the pre-back gate electrodes BG_1 extended in the first direction D1. The pre-back gate electrodes BG_1 may fill a portion of the back gate trench BG T.

Meanwhile, according to some embodiments, before the back gate insulating pattern 113 is formed, a gas-phase doping (GPD) process or a plasma-doping (PLAD) process may be performed. The active layer 202 exposed by the back gate trench BG_T may be doped with impurities through the above-described process.

In one variation, the third electrode pattern BG_M3 shown in FIGS. 11 and 12 may be further formed on the pre-back gate electrode BG_1. The third electrode pattern BG_M3 may fill a portion of the back gate trench BG T.

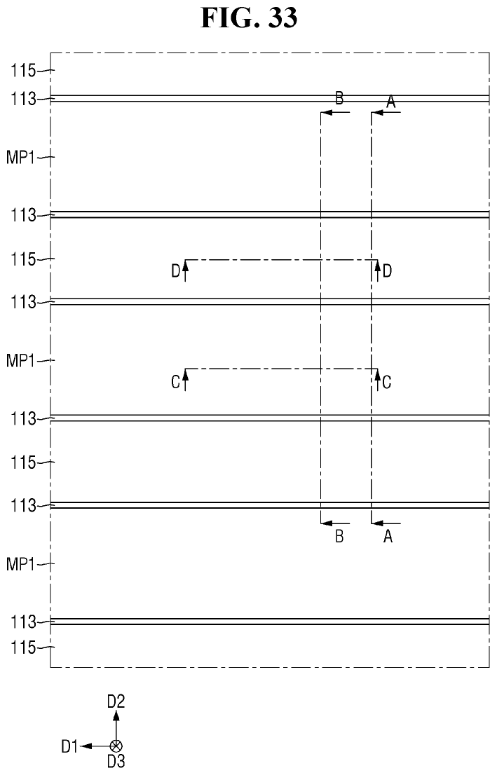

Referring to FIGS. 33 to 38, the back gate capping patterns 115 may be formed on the pre-back gate electrode BG_1.

The back gate capping pattern 115 may fill the remainder of the back gate trench BG_T. When the back gate capping pattern 115 and the back gate insulation pattern 113 are made of the same material (e.g., silicon oxide), the back gate insulation pattern 113 on the upper surface of the back gate mask pattern MP1 may be removed while the back gate capping pattern 115 is being formed.

Before the back gate capping patterns 115 is formed, the gas-phase doping (GPD) process or the plasma doping (PLAD) process may be performed. As a result, the active layer 202 may be doped with impurities through the back gate trench BG_T in which the pre-back gate electrode BG_1 is formed.

After the back gate capping patterns 115 are formed, the first upper mask layer 12 may be removed. The back gate capping patterns 115 may be protruded upward from an upper surface of the first lower mask layer 11.

Then, a spacer layer 120 may be formed along the upper surface of the first lower mask layer 11, sidewalls of the back gate insulating patterns 113 and an upper surface of the back gate capping patterns 115. The spacer layer 120 may be formed to have a uniform thickness. A width of the active patterns of the vertical channel transistors may be determined based on a deposition thickness of the spacer layer 120. The spacer layer 120 may be made of an insulating material. The spacer layer 120 may include, for example, a silicon oxide, a silicon oxynitride, a silicon nitride, a silicon carbide (SiC), a silicon carbon nitride layer (SiCN), or a combination thereof.

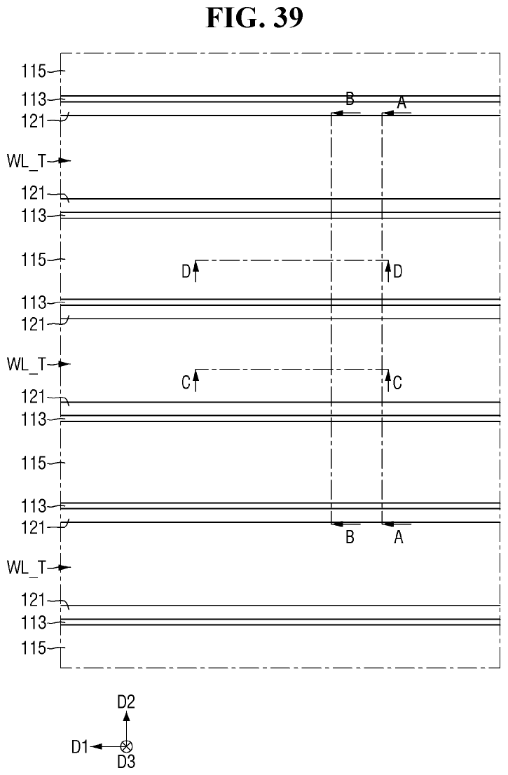

Referring to FIGS. 39 to 44, an anisotropic etching process for the spacer layer 120 may be performed so that a pair of spacer patterns 121 may be formed on the sidewalls of the back gate insulating pattern 113.

The anisotropic etching process for the active layer 202 may be performed using the spacer pattern 121 as an etching mask. As a result, a pair of pre-active patterns (PAP) separated from each other may be formed at both sides of each back gate insulating pattern 113. As the pre-active patterns PAP are formed, the buried insulating layer 201 may be exposed.

The pre-active patterns PAP may have a line shape extended in the first direction D1 in parallel with the pre-back gate electrode BG_1. A word line trench WL_T may be formed between the pre-active patterns PAP adjacent to each other in the second direction D2.

Subsequently, a sacrificial layer for filling the word line trench WL_T may be formed. A mask pattern may be formed on the sacrificial layer. The mask pattern may have a line shape extended in the second direction D2. As another example, the mask pattern may have a line shape extended in the diagonal direction with respect to the first direction D1 and the second direction D2. The sacrificial layer may be etched using the mask pattern as an etching mask, so that sacrificial openings may be formed inside the sacrificial layer.

The pre-active patterns PAP exposed to the sacrificial openings may be etched so that the first active pattern AP1 and the second active pattern AP2 may be formed at both sides of the pre-back gate electrode BG_1. On a first sidewall of the pre-back gate electrode BG_1, the first active patterns AP1 may be formed to be spaced apart from each other in the first direction D1. On a second sidewall of the pre-back gate electrode BG_1, the second active patterns AP2 may be formed to be spaced apart from each other in the first direction D1. As the first active pattern AP1 and the second active pattern AP2 are formed, the sacrificial openings may expose a portion of the back gate insulation pattern 113.

Subsequently, the sacrificial layer, the mask pattern, the spacer pattern 121 and the first lower mask layer 11 may be removed. As a result, the first active pattern AP1 and the second active pattern AP2 may be exposed. In addition, the buried insulating layer 201 may be exposed.

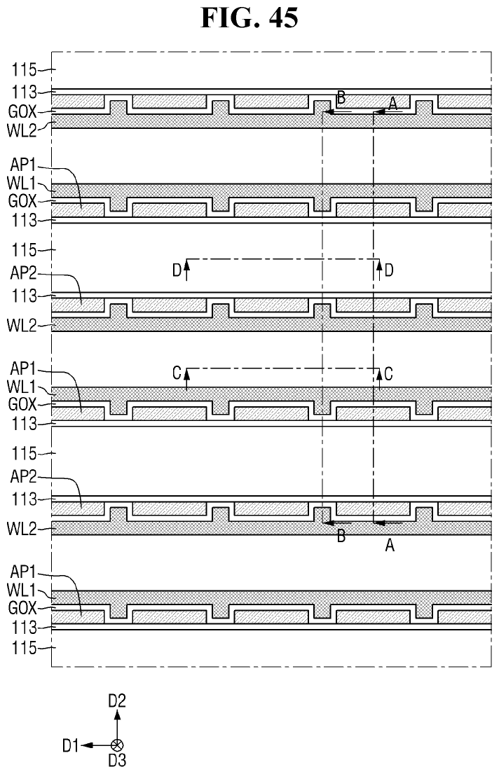

Referring to FIGS. 45 to 47, the gate insulating pattern GOX may be formed along a sidewall of the first active pattern AP1, a sidewall of the second active pattern AP2 and an upper surface of the buried insulating layer 201 on the back gate capping pattern 115.

The gate insulating pattern GOX may be formed using at least one of physical vapor deposition (PVD), thermal chemical vapor deposition (CVD), low-pressure chemical vapor deposition (LP-CVD), plasma-enhanced chemical vapor deposition (PE-CVD) or atomic layer deposition (ALD) techniques, but is not limited thereto.

Then, the first word line WL1 and the second word line WL2 may be formed on the gate insulating pattern GOX. The first and second word lines WL1 and WL2 may be formed on the sidewalls of the first and second active patterns AP1 and AP2.

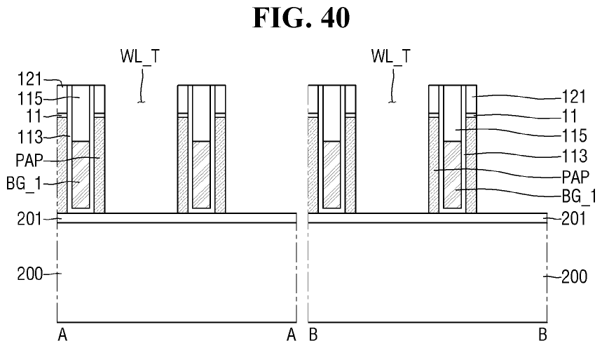

Forming the first and second word lines WL1 and WL2 may include depositing a gate conductive layer on the gate insulating pattern GOX and then performing an anisotropic etching process for the gate conductive layer. In this case, the deposition thickness of the gate conductive layer may be less than a half of a width of the word line trench (WL_T in FIGS. 39 and 40).

In the anisotropic etching process for the gate conductive layer, the gate insulating pattern GOX may be used as an etching stop layer. Unlike the shown example, the gate insulating pattern GOX may be over-etched so that the buried insulating layer 201 may be exposed. In accordance with the anisotropic etching process for the gate conductive layer, the first and second word lines WL1 and WL2 may have various shapes.

An upper surface of the first word line WL1 and an upper surface of the second word line WL2 may be positioned at a lower level than the upper surfaces of the first and second active patterns AP1 and AP2.

For example, after the first and second word lines WL1 and WL2 are formed, the gas-phase doping (GPD) process or the plasma doping (PLAD) process may be performed. As a result, the first and second active patterns AP1 and AP2 may be doped with impurities through the gate insulating pattern GOX exposed by the first and second word lines WL1 and WL2.

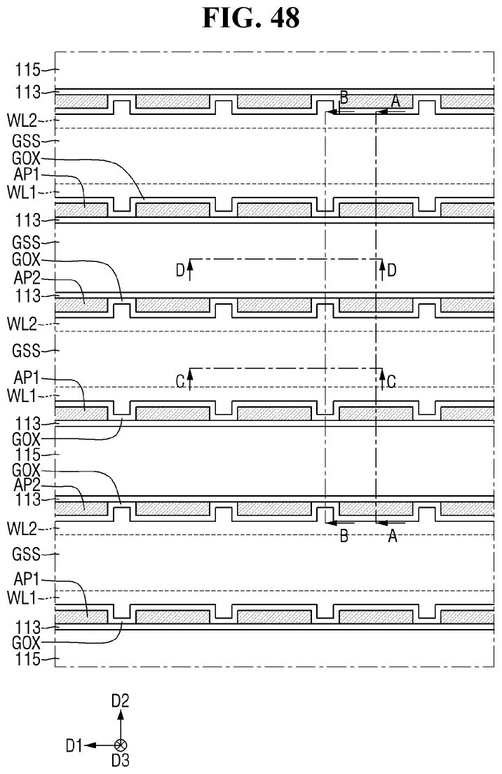

Referring to FIGS. 48 to 50, the gate isolation pattern GSS may be formed on the first word line WL1 and the second word line WL2.

For example, the upper surface of the gate isolation pattern GSS may be on the same plane as the upper surface of the back gate capping pattern 115.

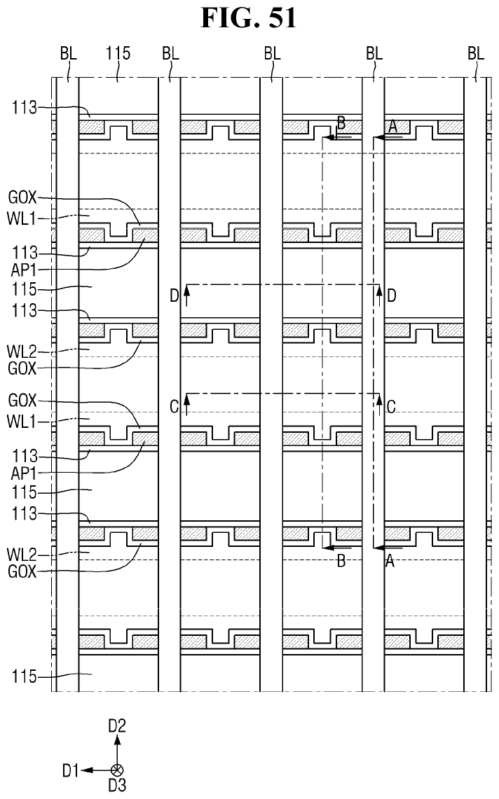

Referring to FIGS. 51 to 53, the bit lines BL extended in the second direction D2 may be formed on the gate isolation pattern GSS and the back gate capping pattern 115.

The bit line BL may include a bit line mask pattern 165, a metal pattern 163 and a semiconductor pattern 161. While the bit lines BL are being formed, a portion of the back gate capping pattern 115 and a portion of the gate isolation pattern GSS may be etched.

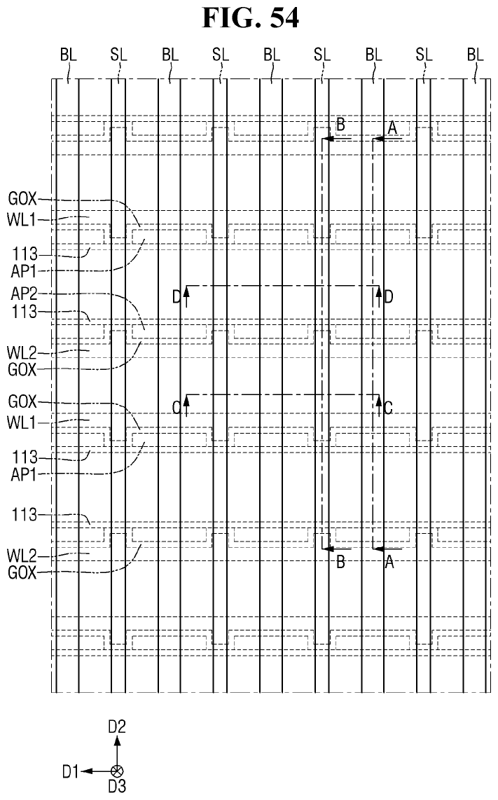

Referring to FIGS. 54 to 56, the shielding conductive line SL may be formed between the bit lines BL adjacent to each other in the first direction D1.

The shielding insulating liner 171 may define a shielding region between the bit lines BL adjacent to each other in the first direction D1. The shielding conductive line SL may be formed inside the shielding region of the shielding insulating liner 171.

The shielding conductive line SL may be formed between the bit lines BL, respectively. For example, forming the shielding conductive line SL may include forming a shielding conductive layer on the shielding insulating liner 171 to fill the shielding region and recessing an upper surface of the shielding conductive layer. Then, the shielding insulating capping layer 175 may be formed on the shielding conductive line SL.

Although not shown, a bonding adhesive layer (263 in FIGS. 2 and 3) may be further formed on the shielding insulating capping layer 175, the shielding insulating liner 171 and the bit line BL.

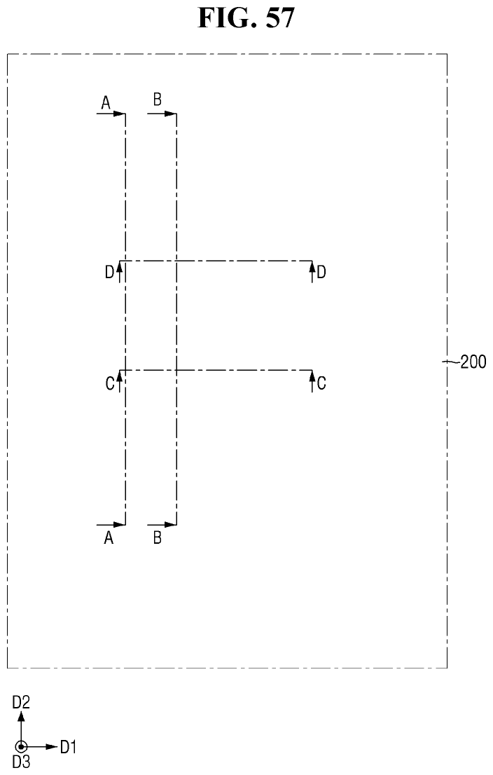

Referring to FIGS. 57 to 59, the sub-substrate 200 in which the pre-back gate electrodes BG_1, the word lines WL1 and WL2, the active patterns AP1 and AP2, the bit lines BL and the shielding conductive line SL are formed may be bonded to the substrate 100.

The substrate 100 and the sub-substrate 200 may be bonded to each other using the bonding adhesive layer 263.

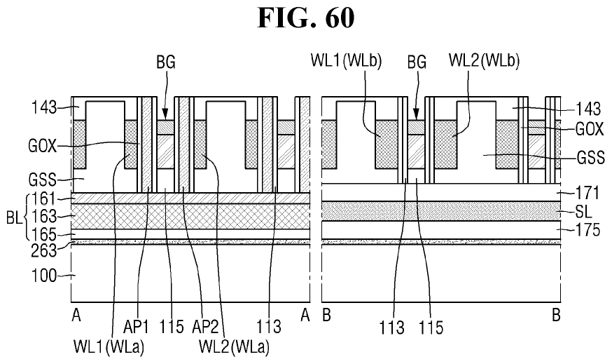

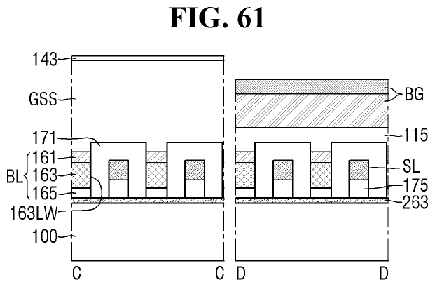

Referring to FIGS. 60 and 61, after the substrate 100 and the sub-substrate 200 are bonded to each other, a backside lapping process of removing the sub-substrate 200 may be performed.

Removing the sub-substrate 200 may include exposing the buried insulating layer 201 by sequentially performing a grinding process and a wet etching process.

Then, the buried insulating layer 201 may be removed to expose the first active pattern AP1 and the second active pattern AP2.

As the buried insulating layer 201 is removed, a portion of the gate insulating pattern GOX and a portion of the back gate insulating pattern 113 may be exposed.

Then, the exposed gate insulating pattern GOX and the exposed back gate insulating pattern 113 may be removed. As a result, the back gate electrode BG, the first word line WL1 and the second word line WL2 may be exposed.

Subsequently, an etch-back process may be performed so that a portion of the first word line WL1 and a portion of the second word line WL2 may be removed. The gate capping pattern 143 may be formed on the first and second word lines WL1 and WL2 that are recessed.

Subsequently, the etch-back process may be performed so that a portion of the pre-back gate electrode BG_1 may be removed. A remaining portion of the pre-back gate electrode BG_1 may be the first electrode pattern (BG_M1 in FIG. 4). The second electrode pattern (BG_M2 in FIG. 4) may be formed on the first electrode pattern (BG_M1 in FIG. 4). Therefore, the back gate electrode BG, which includes the first electrode pattern BG_M1 and the second electrode pattern BG_M2, may be formed.

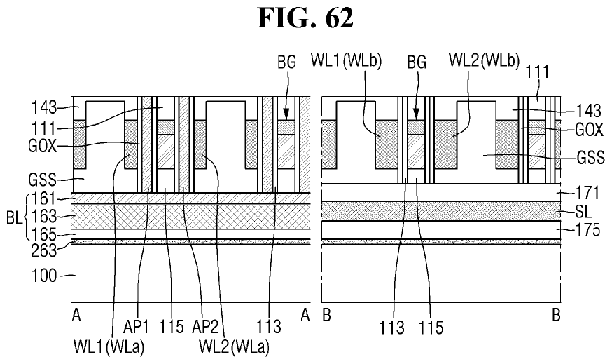

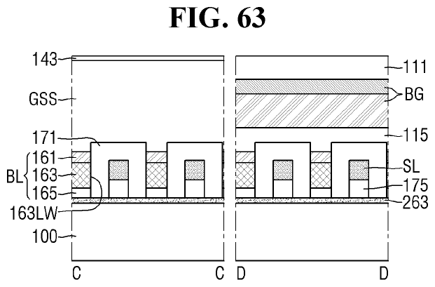

Referring to FIGS. 62 and 63, the back gate isolation pattern 111 may be formed on the back gate electrode BG.

Referring to FIGS. 2 and 3, a contact hole exposing the first active pattern AP1 and the second active pattern AP2 may be formed in the contact etching stop layer 212 and the contact interlayer insulating layer 231. The contact pattern BC may be formed in the contact hole. The contact patterns BC may be formed on the first active pattern AP1 and the second active pattern AP2. The contact patterns BC may be connected to the first active pattern AP1 and the second active pattern AP2. The data storage patterns DSP may be formed on the contact pattern BC.

In concluding the detailed description, those skilled in the art will appreciate that many variations and modifications may be made to the embodiments without substantially departing from the principles of the present disclosure. Therefore, the disclosed embodiments of the present disclosure are used in a generic and descriptive sense only and not for purposes of limitation.

What is claimed is:

1. A semiconductor memory device comprising:
a bit line extended in a first direction on a substrate;
a first word line extended in a second direction on the bit line;
a second word line extended in the second direction on the bit line and spaced apart from the first word line in the first direction;
a back gate electrode between the first word line and the second word line and extended in the second direction;
a first active pattern between the first word line and the back gate electrode on the bit line; and
a second active pattern between the first word line and the back gate electrode on the bit line;
wherein the back gate electrode includes a first region comprising a first conductive material and a second region comprising a second conductive material different from the first conductive material, and
the first region of the back gate electrode is between the second region of the back gate electrode and the bit line.

2. The semiconductor memory device of claim 1, wherein the first region of the back gate electrode is a first electrode pattern of the first conductive material, and
the second region of the back gate electrode is a second electrode pattern of the second conductive material.

3. The semiconductor memory device of claim 2, wherein the back gate electrode further includes a third region between the first region and the bit line, and
the third region of the back gate electrode comprises a third conductive material different from the first conductive material.

4. The semiconductor memory device of claim 1, wherein the first region of the back gate electrode is a first electrode pattern of the first conductive material,
the second region of the back gate electrode is a second electrode pattern comprising a first sub-electrode pattern of the first conductive material and a second sub-electrode pattern of the second conductive material,
the second sub-electrode pattern comprises a pair of vertical portions extended in a third direction, and
the first sub-electrode pattern is between the pair of vertical portions of the second sub-electrode pattern.

5. The semiconductor memory device of claim 4, wherein the first sub-electrode pattern is directly connected to the first electrode pattern.

6. The semiconductor memory device of claim 4, wherein the second sub-electrode pattern further comprises a horizontal portion extended in the first direction and between the first sub-electrode pattern and the first electrode pattern.

7. The semiconductor memory device of claim 4, wherein the second sub-electrode pattern further comprises a horizontal portion extended in the first direction and directly connected to the pair of vertical portions of the second sub-electrode pattern, and the first sub-electrode pattern is directly connected to the first electrode pattern.

8. The semiconductor memory device of claim 4, wherein the back gate electrode further comprises a third region between the first region and the bit line, and
the third region of the back gate electrode comprises a third conductive material different from the first conductive material.

9. The semiconductor memory device of claim 1, wherein the first word line and the second word line comprise a first word line material layer comprising a third conductive material and a second word line material layer comprising a fourth conductive material different from the third conductive material.

10. The semiconductor memory device of claim 1, wherein the first word line comprises a first portion and a second portion that are alternately arranged in the second direction, and
a width of the first portion of the first word line in the first direction is less than a width of the second portion of the first word line in the first direction.

11. The semiconductor memory device of claim 10, wherein
the first active pattern is between a pair of the second portions of the first word line, wherein the pair of the second portions of the first word line are adjacent to each other in the second direction.

12. A semiconductor memory device comprising:
a bit line extended in a first direction on a substrate;
a first active pattern on the bit line;
a second active pattern on the bit line and spaced apart from the first active pattern in the first direction;
a first word line between the first active pattern and the second active pattern and extended in a second direction;
a second word line between the first active pattern and the second active pattern, the second word line extended in the second direction and spaced apart from the first word line in the first direction;
a gate isolation pattern on the bit line, the gate isolation pattern comprising a horizontal portion and a protrusion portion, the horizontal portion is between the first word line and the bit line and between the second word line and the bit line, the protrusion portion is between the first word line and the second word line, and a width of the horizontal portion in the first direction is greater than that of the protrusion portion in the first direction;
a back gate electrode on the bit line, the back gate electrode spaced apart from the first word line and the second word line in the first direction, and the back gate electrode extended in the second direction; and
data storage patterns connected to the first active pattern and the second active pattern,
wherein the back gate electrode comprises a first region comprising a first conductive material and a second region comprising a second conductive material different from the first conductive material, and
the first region of the back gate electrode is between the second region of the back gate electrode and the bit line.

13. The semiconductor memory device of claim 12, wherein the first region of the back gate electrode is a first electrode pattern of the first conductive material, and
the second region of the back gate electrode is a second electrode pattern of the second conductive material.

14. The semiconductor memory device of claim 12, wherein the first region of the back gate electrode is a first electrode pattern of the first conductive material,
the second region of the back gate electrode is a second electrode pattern comprising a first sub-electrode pattern of the first conductive material and a second sub-electrode pattern of the second conductive material,
the second sub-electrode pattern comprises a pair of vertical portions extended in a third direction, and
the first sub-electrode pattern is between the pair of vertical portions of the second sub-electrode pattern.

15. The semiconductor memory device of claim 12, wherein the first word line comprises a first portion and a second portion that are alternately arranged in the second direction,
a width of the first portion of the first word line in the first direction is less than a width of the second portion of the first word line in the first direction, and
the first active pattern is between the second portions of the first word line, wherein the second portions are adjacent to each other in the second direction.

16. A semiconductor memory device comprising:
a peripheral gate structure on a substrate;
a bit line extended in a first direction on the peripheral gate structure;
a shielding conductive line adjacent to the bit line on the peripheral gate structure and extended in the first direction;
a first word line extended in a second direction on the bit line and the shielding conductive line;
a second word line extended in the second direction on the bit line and the shielding conductive line and spaced apart from the first word line in the first direction;
a back gate electrode between the first word line and the second word line and extended in the second direction;
a first active pattern between the first word line and the back gate electrode on the bit line;
a second active pattern between the first word line and the back gate electrode on the bit line;
contact patterns connected to the first active pattern and the second active pattern; and
data storage patterns respectively connected to the contact patterns,
wherein each of the first active pattern and the second active pattern comprises a single crystalline semiconductor material, and
the back gate electrode comprises a first region comprising a first conductive material and a second region comprising a second conductive material different from the first conductive material.

17. The semiconductor memory device of claim 16, wherein the first region of the back gate electrode is a first electrode pattern of the first conductive material, and
the second region of the back gate electrode is a second electrode pattern of the second conductive material.

18. The semiconductor memory device of claim 16, wherein the first region of the back gate electrode is a first electrode pattern of the first conductive material,
the second region of the back gate electrode is a second electrode pattern comprising a first sub-electrode pattern of the first conductive material and a second sub-electrode pattern of the second conductive material,
the second sub-electrode pattern comprises a pair of vertical portions extended in a third direction, and
the first sub-electrode pattern is between the pair of vertical portions of the second sub-electrode pattern.

19. The semiconductor memory device of claim 18, wherein the first sub-electrode pattern is directly connected to the first electrode pattern.

20. The semiconductor memory device of claim 18, wherein the second sub-electrode pattern further comprises a horizontal portion extended in the first direction and directly connected to the pair of vertical portions of the second sub-electrode pattern.
